(19) United States
(12) Patent Application Publication
(10) Pub. No.: US 2026/0321316 A1
(43) Pub. Date: Oct. 15, 2026

(54) MEMORY DEVICE AND OPERATING METHOD THEREOF, AND MEMORY SYSTEM

(71) Applicant: YANGTZE MEMORY TECHNOLOGIES CO., LTD., Wuhan (CN)

(72) Inventors: Leilei XU, Wuhan (CN); Teng ZHOU, Wuhan (CN); Wenli GAO, Wuhan (CN)

(21) Appl. No.: 19/289,717

(22) Filed: Aug. 4, 2025

(30) Foreign Application Priority Data
Apr. 14, 2025 (CN) 2025104658210

(51) Int. Cl. G11C 16/26; G11C 16/14

(52) U.S. Cl. CPC G11C 16/26; G11C 16/14

(57) ABSTRACT

A memory device includes: a memory cell array including a plurality of memory blocks, and a peripheral circuit coupled with the memory cell array and configured to: perform a first read operation on a memory cell included in an edge page in a to-be-read block of the plurality of memory blocks using a first offset read voltage according to the to-be-read block being an open block, wherein the first offset read voltage has a first offset relative to a first read voltage, and the first read voltage is a read voltage corresponding to the first read operation in default read voltages of the to-be-read block.

### CROSS-REFERENCE TO RELATED APPLICATIONS

The present disclosure claims priority to Chinese Patent Application No. 2025104658210, which was filed Apr. 14, 2025, and is hereby incorporated herein by reference in its entirety.

### TECHNICAL FIELD

Examples of the present disclosure relate to the field of semiconductor technology, and in particular to a memory device and an operating method thereof, and a memory system.

### BACKGROUND

Memory devices are storage devices in modern information technology for storing information. As a typical non-volatile semiconductor memory, NAND (Not-And) type memories gradually become mainstream products in the memory market due to high storage density, controllable production cost, suitable program-erase speed and retention characteristics. However, as consumer's requirements for storage devices continue to increase, there is a lot of room for improvement in memory devices and their systems.

### SUMMARY

In view of this, examples of the present disclosure provide a memory device and an operating method thereof, and a memory system.

According to a first aspect, an example of the present disclosure provides a memory device, comprising: a memory cell array comprising a plurality of memory blocks, and a peripheral circuit coupled with the memory cell array and configured to: perform a first read operation on a memory cell included in an edge page in a to-be-read block of the plurality of memory blocks using a first offset read voltage according to the to-be-read block being an open block; the first offset read voltage has a first offset relative to a first read voltage; and the first read voltage is a read voltage corresponding to the first read operation in default read voltages of the to-be-read block.

In some examples, the open block includes at least one blank page including memory cells that are not programmed and at least one program page including memory cells that have been programmed; wherein the at least one program page includes an edge page which is adjacent to one of the at least one blank page in a stacking direction of the to-be-read block.

In some examples, the peripheral circuit is configured to: determine the first offset according to a number of program pages and a first coefficient; the first offset is positively correlated with the number of program pages and is negatively correlated with the first coefficient; and obtain the first offset read voltage according to a difference between the first read voltage and the first offset.

In some examples, the peripheral circuit is further configured to: perform a first correction on the first coefficient according to a program-erase cycle number corresponding to the to-be-read block being in a first preset interval of a plurality of preset intervals, and determine that the first coefficient is a first value; and perform a second correction on the first coefficient according to the program-erase cycle number corresponding to the to-be-read block being in a second preset interval of the plurality of preset intervals which is different from the first preset interval, and determine that the first coefficient is a second value different from the first value; wherein each preset interval of the plurality of preset intervals includes at least one program-erase cycle number, and an average value of the preset interval is an average value of respective program-erase cycle numbers in the preset interval.

In some examples, the open block includes a plurality of program pages which include an edge page and an inner page; the peripheral circuit is further configured to: perform a second read operation on a memory cell included in the inner page using a second offset read voltage; the second offset read voltage has a second offset relative to the second read voltage; the second read voltage is a read voltage corresponding to the second read operation in the default read voltages; wherein the second offset is less than the first offset.

In some examples, the peripheral circuit is configured to: determine the second offset according to the number of program pages and a second coefficient; the second offset is positively correlated with the number of program pages and is negatively correlated with the second coefficient; and obtain the second offset read voltage according to a difference between the second read voltage and the second offset.

In some examples, the peripheral circuit is further configured to: perform a first correction on the second coefficient according to a program-erase cycle number corresponding to the to-be-read block being in a first preset interval of a plurality of preset intervals, and determine that the second coefficient is a first value; and perform a second correction on the second coefficient according to the program-erase cycle number corresponding to the to-be-read block being in a second preset interval of the plurality of preset intervals which is different from the first preset interval, and determine that the second coefficient is a second value different from the first value; wherein each preset interval of the plurality of preset intervals includes at least one program-erase cycle number, and an average value of the preset interval is an average value of respective program-erase cycle numbers in the preset interval.

In some examples, the peripheral circuit is further configured to: define the plurality of preset intervals according to a preset program-erase cycle number of the memory device, the plurality of preset intervals comprise M intervals from a first interval to a M-th interval; wherein a number of the M intervals is positively correlated with a magnitude of the preset program-erase cycle number; wherein M is a positive integer and M≥2.

In some examples, the peripheral circuit is further configured to: determine the first offset or the second offset according to additional information; wherein the additional information includes a retention state or an interference state of the data stored in a memory cell included in the edge page or the inner page is.

In some examples, the peripheral circuit is further configured to: perform a third read operation on a memory cell included in a page in the to-be-read block of the plurality of memory blocks using a third read voltage according to the to-be-read block being a close block; the third read voltage is a read voltage corresponding to the third read operation in the default read voltages; and memory cells included in any page of the close block have been programmed.

In some examples, a number of bits stored in the memory cell is N, and the memory cell has 2^{N} memory states; 2^{N} memory states include an erase state and 2^{N}−1 non-erase states; wherein N is a positive integer; the default read voltages include 2^{N}−1 read voltages from a first level read voltage to a (2^{N}−1)-th level read voltage; the first read voltage is one of 2^{N}−1 read voltages; and the first offset is associated with the first read voltage.

In some examples, the first offset is determined to be the first value according to the first read voltage being a read voltage of the 2^{N}−1 read voltages; and the first offset is determined to be the second value different from the first value according to the first read voltage being another read voltage of the 2^{N}−1 read voltages which is different from the read voltage.

According to a second aspect, an example of the present disclosure provides an operating method of a memory device, comprising: performing, by a peripheral circuit of the memory device coupled with a memory cell array of the memory device, a first read operation on a memory cell included in an edge page in a to-be-read block of a plurality of memory blocks of the memory cell array using a first offset read voltage according to the to-be-read block being an open block; the first offset read voltage has a first offset relative to a first read voltage; and the first read voltage is a read voltage corresponding to the first read operation in default read voltages of the to-be-read block.

In some examples, the open block includes at least one blank page including memory cells that are not programmed and at least one program page including memory cells that have been programmed; wherein the at least one program page includes an edge page which is adjacent to one of the at least one blank page in a stacking direction of the to-be-read block.

In some examples, the operating method comprises: determining the first offset according to a number of program pages and a first coefficient; the first offset is positively correlated with the number of program pages and is negatively correlated with the first coefficient; and obtaining the first offset read voltage according to a difference between the first read voltage and the first offset.

In some examples, the operating method further comprises: performing a first correction on the first coefficient according to a program-erase cycle number corresponding to the to-be-read block being in a first preset interval of a plurality of preset intervals, and determining that the first coefficient is a first value; and performing a second correction on the first coefficient according to the program-erase cycle number corresponding to the to-be-read block being in a second preset interval of the plurality of preset intervals which is different from the first preset interval, and determining that the first coefficient is a second value different from the first value; wherein each preset interval of the plurality of preset intervals includes at least one program-erase cycle number, and an average value of the preset interval is an average value of respective program-erase cycle numbers in the preset interval.

In some examples, the operating method further comprises: performing a second read operation on a memory cell included in the inner page using a second offset read voltage; the second offset read voltage has a second offset relative to the second read voltage; the second read voltage is a read voltage corresponding to the second read operation in the default read voltages; wherein the second offset is less than the first offset; wherein the open block includes a plurality of program pages which include an edge page and an inner page.

In some examples, the operating method comprises: determining the second offset according to the number of program pages and a second coefficient; the second offset is positively correlated with the number of program pages and is negatively correlated with the second coefficient; and obtaining the second offset read voltage according to a difference between the second read voltage and the second offset.

In some examples, the operating method further comprises: performing a first correction on the second coefficient according to a program-erase cycle number corresponding to the to-be-read block being in a first preset interval of a plurality of preset intervals, and determining that the second coefficient is a first value; and performing a second correction on the second coefficient according to the program-erase cycle number corresponding to the to-be-read block being in a second preset interval of the plurality of preset intervals which is different from the first preset interval, and determining that the second coefficient is a second value different from the first value; wherein each preset interval of the plurality of preset intervals includes at least one program-erase cycle number, and an average value of the preset interval is an average value of respective program-erase cycle numbers in the preset interval.

In some examples, the operating method further comprises: defining the plurality of preset intervals according to a preset program-erase cycle number of the memory device, the plurality of preset intervals comprise M intervals from a first interval to a M-th interval; wherein a number of the M intervals is positively correlated with a magnitude of the preset program-erase cycle number; wherein M is a positive integer and M≥2.

In some examples, the operating method further comprises: determining the first offset or the second offset according to additional information; wherein the additional information includes a retention state or an interference state of the data stored in a memory cell included in the edge page or the inner page is.

In some examples, the operating method further comprises: performing a third read operation on a memory cell included in a page in the to-be-read block of the plurality of memory blocks using a third read voltage according to the to-be-read block being a close block; the third read voltage is a read voltage corresponding to the third read operation in the default read voltages; and memory cells included in any page of the close block have been programmed.

According to a third aspect, an example of the present disclosure provides a memory system, comprising: a memory device configured to: receive a read command, and perform a first read operation on a memory cell included in an edge page in a to-be-read block of the memory device using a first offset read voltage, wherein the first offset read voltage has a first offset relative to a first read voltage, and the first read voltage is a read voltage corresponding to the first read operation in default read voltages of the to-be-read block; and a memory controller coupled with the memory device and controlling the memory device, wherein the memory controller is configured to: send a read command.

In some examples, the memory controller is further configured to: send a first instruction indicating to obtain the first offset read voltage; the memory device is further configured to: receive the first instruction, and obtain first information representing the first offset read voltage; and send to the memory controller second information representing that the first information is obtained; the memory controller is further configured to: send a read command according to the second information; and the memory device is further configured to: receive the read command, generate a first offset read voltage according to the first information, and control the memory device to perform the first read operation according to the first offset read voltage.

In some examples, the memory controller is configured to: send a first instruction which includes open block information; the open block information includes information representing that the to-be-read block is an open block, information representing that a to-be-read page in the to-be-read block is an edge page, and information representing that the first offset is associated with the edge page; and the memory device is configured to: receive the first instruction, and obtain first information representing the first offset read voltage based on the open block information; and send to the memory controller the second information representing that the first information is obtained.

In some examples, the memory controller is further configured to: send a read command; the read command includes a first instruction indicating to obtain the first offset read voltage; the memory device is further configured to: receive the read command, and obtain first information representing the first offset read voltage; and generate a first offset read voltage according to the first information, and control the memory device to perform the first read operation according to the first offset read voltage.

In some examples, the memory controller is configured to: send a read command; the read command includes a first instruction which includes open block information; the open block information includes information representing that the to-be-read block is an open block, information representing that a to-be-read page in the to-be-read block is an edge page, and information representing that the first offset is associated with the edge page; and the memory device is configured to: receive the read command, and obtain first information representing the first offset read voltage based on the open block information.

In some examples, the open block information further includes information representing a number of program pages in the to-be-read block and information representing a first coefficient; the information representing that the first offset is associated with the edge page includes information representing that the first offset is positively correlated with the number of program pages and is negatively correlated with the first coefficient; the memory device is configured to: determine information representing the first offset based on the information representing the number of program pages, the information representing the first coefficient, and the information representing that the first offset is positively correlated with the number of program pages and is negatively correlated with the first coefficient; and obtain the information representing the first offset read voltage according to the information representing the first read voltage and the information representing the first offset.

In some examples, the open block includes at least one blank page including memory cells that are not programmed and at least one program page including memory cells that have been programmed; wherein the at least one program page includes an edge page which is adjacent to one of the at least one blank page in a stacking direction of the to-be-read block; the open block includes a plurality of program pages which include an edge page and an inner page; the memory device is further configured to: perform a second read operation on a memory cell included in the inner page using a second offset read voltage; the second offset read voltage has a second offset relative to the second read voltage; the second read voltage is a read voltage corresponding to the second read operation in the default read voltages; wherein the second offset is less than the first offset.

In some examples, the open block information further includes information representing the number of program pages in the to-be-read block and information representing a second coefficient; the information representing that the second offset is associated with the edge page includes information representing that the second offset is positively correlated with the number of program pages and is negatively correlated with the second coefficient; the memory device is configured to: determine information representing the second offset based on the information representing the number of program pages, the information representing the second coefficient, and the information representing that the second offset is positively correlated with the number of program pages and is negatively correlated with the second coefficient; and obtain the information representing the second offset read voltage according to the information representing the second read voltage and the information representing the second offset; wherein the second offset is less than the first offset.

In the examples of the present disclosure, the first read operation is performed on the memory cell included in the edge page using the first offset read voltage according to the to-be-read page being an edge page of an open block, so that the first read operation logic of processing the open block by the peripheral circuit of the memory device is simplified, which facilitates reducing the complexity of the first read operation processing, for example, facilitates reducing the memory space occupied by the first offset table (comprising the mapping relationship between the first offset and the edge word line) corresponding to the first offset read voltage, which facilitates reducing the fail bit count (FBC) of the first read operation.

### BRIEF DESCRIPTION OF THE DRAWINGS

FIG. 1 is a schematic diagram of an example of a system having a memory system according to an example of the present disclosure;

FIG. 2A is a schematic diagram of an example of a memory card having a memory system according to an example of the present disclosure;

FIG. 2B is a schematic diagram of an example of a solid state drive having a memory system according to an example of the present disclosure;

FIG. 3A is a schematic diagram of distribution of memory cells of a 3D NAND type memory according to an example of the present disclosure;

FIG. 3B is a schematic three-dimensional circuit diagram of an example of a memory device according to the present disclosure;

FIG. 3C is a schematic two-dimensional circuit diagram of an example of a memory device according to the present disclosure;

FIG. 4 is a schematic cross-sectional view of a memory cell array comprising a NAND type memory string according to an example of the present disclosure;

FIG. 5 is a schematic diagram of an example of a memory device comprising a memory cell array and a peripheral circuit according to an example of the present disclosure;

FIG. 6 is a schematic diagram of an example of a read operation process of a memory system according to the present disclosure;

FIG. 7 is a schematic diagram of threshold voltage distribution corresponding to a memory cell comprising 3 memory bits according to an example of the present disclosure;

FIG. 8A is a schematic diagram of an open block having an edge page of a memory device according to the present disclosure;

FIG. 8B is a schematic diagram of an open block having an edge page and an inner page of a memory device according to the present disclosure;

FIG. 8C is another schematic diagram of an open block having an edge page and an inner page of a memory device according to the present disclosure;

FIG. 9 is a first schematic diagram of an example of a process of setting an offset read voltage of a memory device according to the present disclosure;

FIG. 10 is a second schematic diagram of an example of a process of setting an offset read voltage of a memory device according to the present disclosure;

FIG. 11 is a third schematic diagram of an example of a process of setting an offset read voltage of a memory device according to the present disclosure;

FIG. 12 is a schematic diagram of a relationship between an index of a word line coupled to an edge page in an open block of a memory device and a voltage value of a first offset according to the present disclosure;

FIG. 13 is a schematic diagram of a relationship between an index of a word line coupled to an inner page in an open block of a memory device and a voltage value of a second offset according to the present disclosure;

FIG. 14 is a diagram of an example of a threshold voltage distribution in a first read operation and a second read operation of a memory device according to the present disclosure;

FIG. 15 is a schematic diagram of example of components structure with a memory system according to an example of the present disclosure.

### DETAILED DESCRIPTION

Example of implementations applied in the present disclosure will be described in more detail below with reference to the accompanying drawings. Although example of implementations of the present disclosure are shown in the accompanying drawings, it is to be understood that the present disclosure may be implemented in various forms and should not be limited to the implementations set forth herein. Rather, these examples are provided so that the present disclosure can be more thoroughly understood and the scope of the present disclosure can be fully conveyed to those skilled in the art.

In the following description, numerous details are presented in order to provide a more thorough understanding of the present disclosure. However, it will be apparent to one skilled in the art that the present disclosure may be practiced without one or more of these details. In other examples, in order to avoid confusion with the present disclosure, some technical features known in the art are not described; for example, not all features of the actual example are described here, and well-known functions and structures are not described in detail.

In addition, the drawings are merely schematic illustrations of the present disclosure, and are not necessarily drawn to scale. Like reference numerals in the drawings refer to the same or similar parts, and repeated description thereof will be omitted. Some of the memory block diagrams shown in the drawings are functional entities and do not necessarily have to correspond to physically or logically separated entities. These functional entities may be implemented in software form, or implemented in one or more hardware modules or integrated circuits, or implemented in different networks and/or processor devices and/or microcontroller devices.

The flowchart shown in the drawings is merely for example and not necessarily all operations. For example, some operations may be further decomposed, and some operations may be combined or partially combined, so the actual execution sequence may be changed according to actual conditions.

A term used herein is for the purpose of describing a particular example only and is not to be considered as limitation of the present disclosure. As used herein, the singular forms “a”, “an” and “said/the” are intended to include the plural forms as well, unless the context clearly dictates otherwise. It should also be understood that the terms “consists of”, “includes” and/or “comprise”, when used in this description, identify the presence of stated features, integers, operations, operations, elements and/or components, but do not exclude the presence of one or more other features, integers, operations, operations, elements, components and/or groups. As used herein, the term “and/or” includes any and all combinations of the associated listed items.

Memory devices in examples of the present disclosure include but are not limited to a three-dimensional NAND memory, and for ease of understanding, a three-dimensional NAND memory is used as an example for illustration.

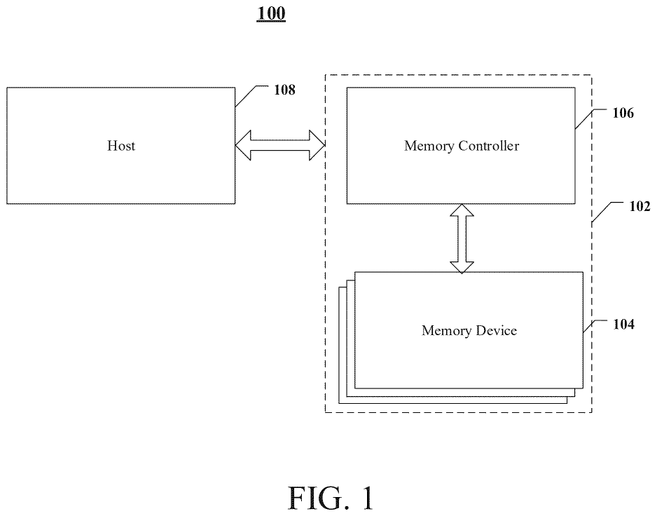

FIG. 1 illustrates a block diagram of an example of system 100 with memory devices in accordance with some aspects of the present disclosure. The system 100 may be a mobile phone, a desktop computer, a laptop computer, a tablet, a vehicle computer, a gaming console, a printer, a positioning device, a wearable electronic device, a smart sensor, a Virtual Reality (VR) device, an Augment Reality (AR) device, or any other suitable electronic devices having storage therein. As shown in in FIG. 1, system 100 may include a host 108 and a memory system 102, and the memory system 102 has one or more memory devices 104 and a memory controller 106. The host 108 may be a processor of an electronic device (e.g., a Central Processing Unit (CPU)) or a System of Chip (SoC) (e.g., an Application Processor (AP)). Host 108 may be configured to send data to or receive data from memory device 104.

According to some implementations, memory controller 106 is coupled to memory device 104 and host 108 and is configured to control memory device 104. Memory controller 106 may manage data stored in memory device 104 and communicate with host 108. In some implementations, the memory controller 106 is designed to operate in low duty cycle environments, e.g., Secure Digital (SD) card, Compact Flash (CF) card, Universal Serial Bus (USB) flash drive, or other media for use in electronic devices such as personal computer, digital camera, mobile phone, etc.

In some implementations, the memory controller 106 is designed to operate in high duty cycle environment Solid State Drive (SSD) or embedded Multi Media Card (eMMC), wherein SSD or eMMC is used as data storage for mobile devices such as smartphone, tablet computer, laptop computer, and enterprise storage array.

Memory controller 106 may be configured to control operations of memory device 104, e.g., read, erase and program operations. Memory controller 106 may also be configured to manage various functions related to data stored or to be stored in memory device 104, including but not limited to bad block management, garbage collection, logical-to-physical address translation, wear leveling, etc. In some implementations, memory controller 106 is also configured to process error correction code related to data read from or written to memory device 104.

The memory controller 106 may also perform any other suitable functions, e.g., formatting the memory device 104. Memory controller 106 may communicate with external devices (e.g., host 108) according to a particular communication protocol. For example, the memory controller 106 may communicate with external devices through at least one of various interface protocols, such as USB protocol, MMC protocol, Peripheral Component Interconnection (PCI) protocol, PCI Express (PCI-E) protocol, Advanced Technology Attachment (ATA) protocol, Serial ATA protocol, Parallel ATA protocol, Small Computer Small Interface (SCSI) protocol, Enhanced Small Disk Interface (ESDI) protocol, Integrated Drive Electronics (IDE) protocol, Firewire protocol, etc.

The memory controller 106 and one or more memory device 104 may be integrated into various types of storage devices, e.g., included in the same package (e.g., Universal Flash Storage (UFS) package or eMMC package). For example, memory system 102 may be implemented and packaged into different types of terminal electronic products.

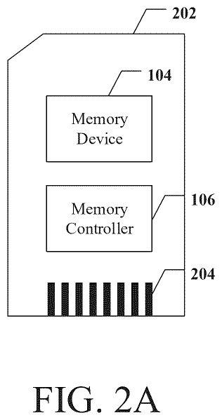

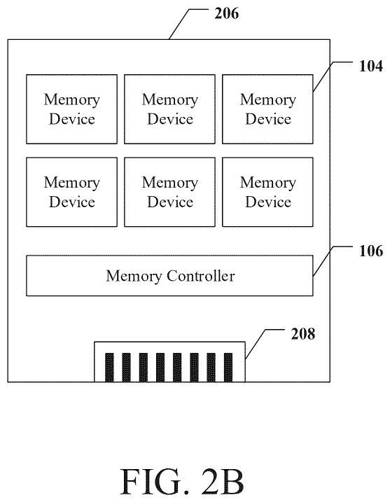

In one example as shown in FIG. 2A, memory controller 106 and a single memory device 104 may be integrated into a memory card 202. Memory card 202 may include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 202 may further include a memory card connector 24 coupling memory card 202 with a host (e.g., host 108 in FIG. 1).

In another example as shown in FIG. 2B, memory controller 106 and multiple memory devices 104 may be integrated into a SSD 206. The SSD 206 may further include an SSD connector 208 coupling the SSD 206 with a host (e.g., host 108 in FIG. 1). In some implementations, the storage capacity and/or operating speed of the SSD 206 is greater than the storage capacity and/or operating speed of memory card 202.

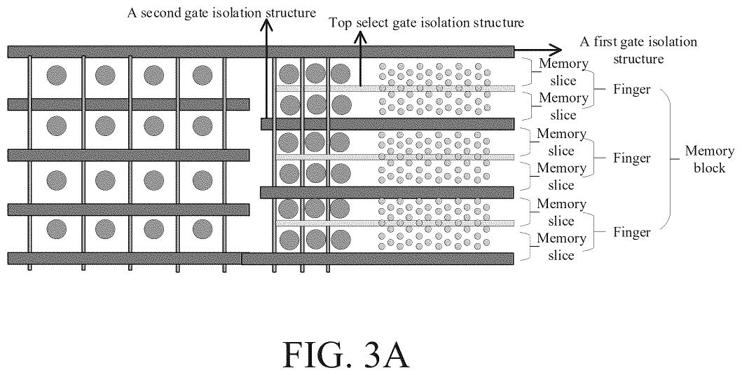

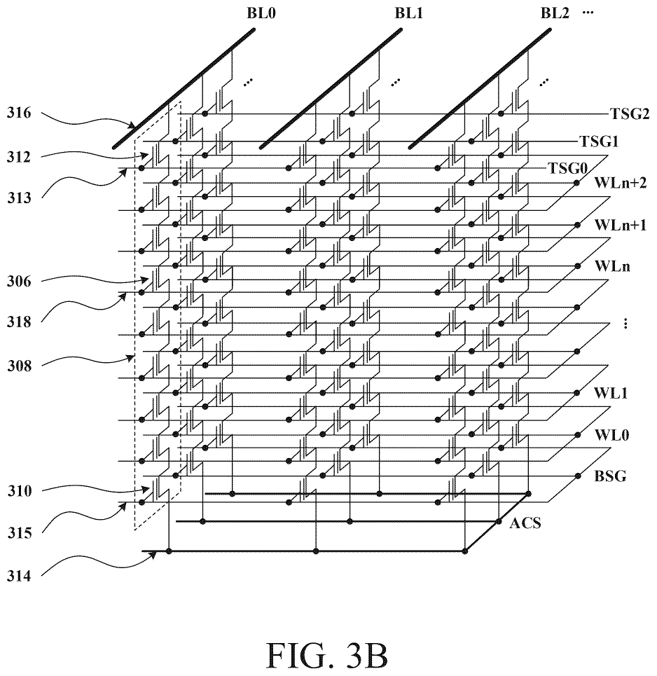

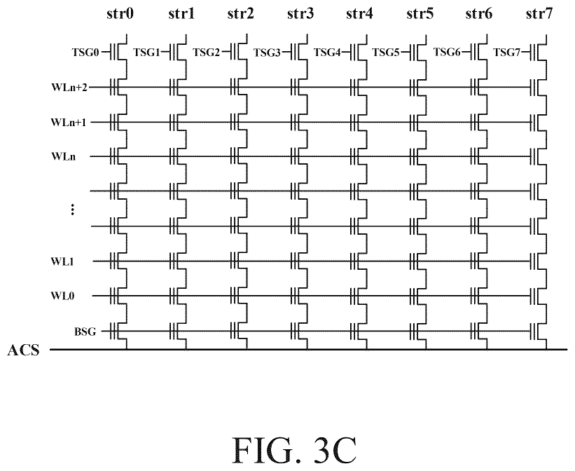

FIG. 3A exemplarily shows a schematic structural diagram of a memory cell array of a three-dimensional NAND type memory As shown in FIG. 3A, a memory cell array of the three-dimensional NAND type memory consists of a plurality of rows of memory cell rows parallel to each other and parallel to a gate isolation structure, each two rows of memory cell rows are separated by the gate isolation structure and an top select gate isolation structure, and each memory cell row includes a plurality of memory cells. The gate isolation structure may include a first gate isolation structure and a second gate isolation structure. The first gate isolation structure divides the memory cell array into a plurality of memory blocks (expressed as Block), the plurality of second gate isolation structures may divide the memory block into a plurality of fingers (expressed as Finger), and an top select gate isolation structure disposed in the middle of each finger may divide the finger into two portions, thereby dividing the finger into two memory slices. In actual application, a number of fingers included in a memory block may be adjusted according to actual conditions, such as 2, 3, 4, 5, and the like.

It should be noted that the number of memory cell rows between the gate isolation structure and the top select gate isolation structure presented in FIG. 3A is merely for example and is not intended to limit the number of memory cell rows included in a finger of the three-dimensional NAND type memory in the present disclosure. In practical applications, the number of memory cell rows included in a finger may be adjusted according to actual conditions, such as 2, 4, 8, 16, etc.

FIG. 3B illustrates a schematic three-dimensional circuit diagram according to an example of a memory device of the present disclosure. The memory device may be an example of memory device 104 in FIG. 1. The memory device may include a memory cell array and a peripheral circuit coupled with the memory cell array. Taking an example in which the memory cell array is a three-dimensional NAND type memory cell array for illustration, wherein memory cells 306 are NAND type memory cells, and memory cells 306 are provided in the form of an array of memory strings 308, each memory string 308 extending vertically over a substrate (not shown). In some implementations, each memory string 308 includes multiple memory cells 306 coupled in series and stacked vertically. Each memory cell 306 may retain a continuous analog value, e.g., voltage or charge, depending on the number of electrons trapped within the region of the memory cell 306. Each memory cell 306 may be a “floating gate” type memory cell comprising a floating gate transistor, or a “charge trap” type memory cell comprising a charge trap transistor.

In some implementations, each memory cell 306 is a Single-level Cell (SLC) that has two possible memory states and may thus store one bit of data. For example, a first memory state of “0 ” may correspond to a first voltage range, and a second memory state of “1” may correspond to a second voltage range. In some implementations, each memory cell 306 is a Multi-Level Cell (MLC) capable of storing more than a single bit of data in more than four memory states. For example, an MLC may store two bits per cell (also known as a Double-Level Cell), three bits per cell (also known as a Trinary-Level Cell (TLC)), four bits per cell (also known as a Quad-Level Cell (QLC)), five bits per cell (also known as a Penta-level cell (PLC)), or more than five bits per cell. Each MLC can be programmed to assume a range of possible nominal storage values. In one example, if each MLC stores two bits of data, the MLC can be programmed to assume one of three possible program levels from the erased state through writing one of three possible nominal storage values into the cell, and a fourth nominal storage value may be used for the erase state.

It is to be noted that the storage state mentioned here is also the storage state of the memory cell mentioned in this application. Different memory cells have different numbers of storage states. e.g., a SLC type memory cell has two storage states (e.g., two memory states), wherein the two storage states include a program state and an erase state. As another example, an MLC type memory cell has four storage states, wherein the four storage states include one erase state and three program states. As yet another example, a TLC type memory cell has eight storage states, wherein the eight storage states include one erase state and seven program states. In some implementation, the QLC type memory cell has sixteen storage states, wherein the sixteen storage states include one erase state and fifteen program states.

As shown in FIG. 3B, each memory string 308 may include a bottom select transistor 310 (also referred to as a source-side select transistor) at its source terminal and an top select transistor 312 (also referred to as a drain-side select transistor) at its drain terminal, the gate of the bottom select transistor 310 is connected to the bottom select gate line (BSG), and the gate of the top select transistor 312 is connected to the top select gate line (TSG). The bottom select transistor 310 and the top select transistor 312 may be configured to activate the selected memory string 308 during read and program operations. In some implementations, the sources of the memory strings 308 in the same memory block are coupled through the same source line (SL) 314 (e.g., array common source (ACS)). In other words, according to some implementations, all memory strings 308 in the same memory block are coupled to an array common source (ACS). According to some implementations, the drain of the top select transistor 312 of each memory string 308 is connected to a respective bit line 316 from which data may be read or written via an output bus (not shown). In some implementations, each memory string 308 is configured to be selected or deselected by applying a select voltage (e.g., higher than a threshold voltage of the top select transistor 312) or a deselect voltage (e.g., 0V) to the respective top select transistor 312 via one or more top select gate lines 313 (corresponding to one or more top select transistors 312) and/or by applying a select voltage (e.g., higher than a threshold voltage of the bottom select transistor 310) or a deselect voltage (e.g., 0V) to the respective bottom select transistor 310 via one or more bottom select gate lines 315 (corresponding to one or more bottom select transistors 310).

As shown in FIG. 3B, a NAND memory string 308 may be organized into multiple memory blocks, each of which may have a common source line 314 (e.g., coupled to ground). In some implementations, each memory block is the basic data unit for an erase operation, e.g., all memory cells 306 on the same memory block are erased simultaneously. To erase the memory cell 306 in the selected memory block, the source line 314 coupled to the selected memory block and to the unselected memory blocks in the same plane as the selected memory block may be biased with an erase voltage (Vers) (e.g., a high positive voltage (e.g., 20V or higher)). It is to be understood that, in some examples, erase operations may be performed at the half-memory block level, at the quarter-memory block level, or at a level with any suitable number of memory blocks or any suitable fraction of memory blocks. The memory cells 306 of adjacent NAND memory strings 308 may be coupled through a word line 318, which may be biased coupled to selected word lines with read and program voltages V_{WL} (e.g., read voltage (e.g., 0.3V), program voltage (e.g., 3V)), and selecting which row of memory cells 306 is affected by read and program operations.

Referring to FIG. 3B, a gate of each of the plurality of memory cells 306 is connected to a respective word line 318, each memory string 308 is coupled to a respective bit line 316 through a respective top select transistor 312, and a bottom select transistor 310 is coupled to a respective source line 314.

Referring to FIG. 3B, a memory block includes an array of memory strings coupled with word line WL0, word line WL1, . . . , word line WLn, word line WLn+1, and word line WLn+2 that are stacked. Each memory string of a column of memory strings in an array of memory strings is connected to a bit line (e.g., bit line BL0) through respective top select transistors and to the array common source ACS through respective bottom select transistors. The gates of the top select transistors of a column of memory strings are connected to respective top select gate lines respectively. The gates of the bottom select transistors of a column of memory strings are collectively connected to the bottom select gate line BSG. Each memory string of a row of memory strings in an array of memory strings is connected to a respective bit line through respective top select transistors and to an array common source ACS through respective bottom select transistors. The gates of the top select transistors of a row of memory strings are collectively connected to a top select gate line (e.g., top select gate line TSG0). The gates of the bottom select transistors of a row of memory strings are collectively connected to the bottom select gate line BSG. In some examples, a row of memory strings may be selected by a top select gate line, and a plurality of memory cells coupled with a word line in the memory cells of a memory string coupled with a top select gate line (e.g., top select gate line TSG0) may be defined as a page. In some examples, the memory cells coupled with a word line may include a plurality of pages, each page being selected/deselected by a respective top select gate line.

FIG. 3C is a schematic two-dimensional circuit diagram of an example of a memory device of the present disclosure. Referring to FIG. 3C, a memory device includes a plurality of memory slices, and a memory slice includes a plurality of memory strings. Different memory strings in the memory slice are connected to respective bit lines through respective top select transistors, and are connected to the array common source through respective bottom select transistors. For example, the memory device includes a memory slice str0, a memory slice str1, a memory slice str2, a memory slice str3, a memory slice str4, a memory slice str5, a memory slice str6, and a memory slice str7. The N different memory strings in the memory slice are respectively connected to the bit line BL0 to the bit line BLN-1, wherein N is a natural number. Along the extending direction of the bit line, each bit line is connected to a memory string in a different memory slice. For example, a bit line is connected to the second ends of a memory string of the memory slice str0, a memory string of the memory slice str1, a memory string of the memory slice str2, a memory string of the memory slice str3, a memory string of the memory slice str4, a memory string of the memory slice str5, a memory string of the memory slice str6, and a memory string of the memory slice str7. The gates of the top select transistors of a memory string of the memory slices str0 to str7 are connected to the top select gate line TSG0, the top select gate line TSG1, the top select gate line TSG2, the top select gate line TSG3, the top select gate line TSG4, the top select gate line TSG5, the top select gate line TSG6, and the top select gate line TSG7, respectively. The gates of the bottom select transistors of a memory string of the memory slices str0 to str7 are collectively connected to the bottom select gate line BSG. For example, memory cells coupled with a word line may include 8 pages selected by respective top select gate lines. Although the number of memory slices is 8 in FIG. 3C, the number of memory slices may also be other numbers less than 8 or greater than 8, such as 4, 10.

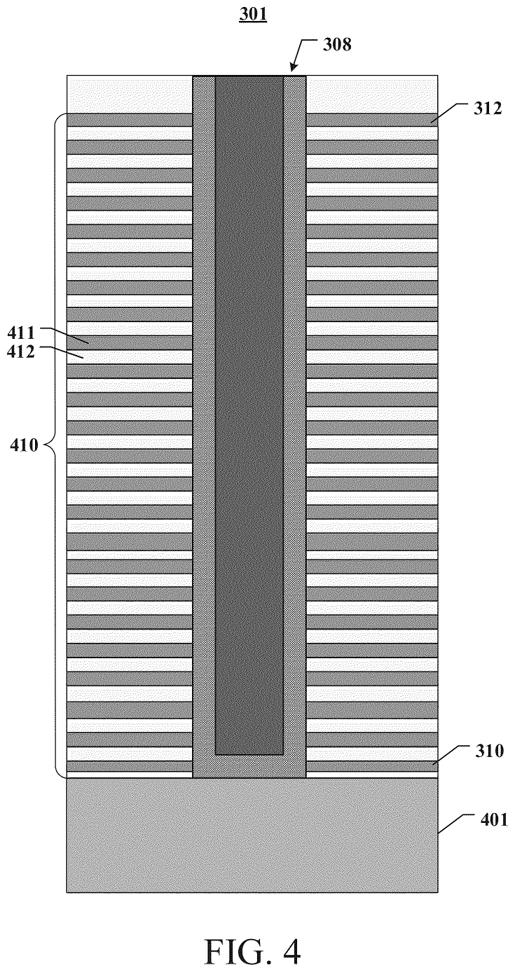

FIG. 4 illustrates a schematic cross-sectional view of an example of a memory cell array comprising memory strings 308, e.g., NAND, according to some aspects of the present disclosure. As shown in FIG. 4, the NAND memory cell array may include a stacked structure 410, the stacked structure 410 includes multiple gate layers 411 and multiple insulating layers 412 alternately stacked in sequence, and the channel structure vertically penetrating through the gate layers 411 and the insulating layers 412, wherein the channel structure is coupled to each gate layer to form a memory cell, and the channel structure is coupled to multiple gate layers in the stacked structure 410 to form the memory string 308. Gate layers 411 and the insulating layers 412 may be stacked alternately, and two adjacent gate layers 411 are separated by an insulating layer 412.

A constituent material of the gate layer 411 may include a conductive material. Conductive materials include, but are not limited to, tungsten (W), cobalt (Co), copper (Cu), aluminum (Al), polysilicon, doped silicon, silicide, or any combination thereof. In some examples, each gate layer 411 includes a metal layer, e.g., a tungsten layer. In some examples, each gate layer 411 includes a doped polysilicon layer. Each gate layer 411 may include a control gate surrounding a memory cell. A gate layer 411 at the top of a stacked structure 410 may extend laterally as a top select gate line, a gate layer 411 at the bottom of a stacked structure 410 may extend laterally as a bottom select gate line, and a gate layer 411 extending laterally between a top select gate line and a bottom select gate line may serve as a word line.

In some examples, a stacked structure 410 may be disposed on a substrate 401. The substrate 401 may include silicon (e.g., monocrystalline silicon), silicon germanium (SiGe), gallium arsenide (GaAs), germanium (Ge), silicon-on-insulator (SOI), germanium-on-insulator (GOI), or any other suitable materials.

In some examples, a memory string 308 includes a channel structure extending vertically through stacked structure 410. In some implementations, a channel structure includes a channel hole filled with semiconductor material(s) (e.g., as a semiconductor channel) and dielectric material(s) (e.g., as a memory film). In some implementations, a semiconductor channel includes silicon, e.g., polysilicon. In some implementations, a memory film is a composite dielectric layer comprising a tunneling layer, a storage layer (also referred to as a “charge trapping/storage layer”), and a blocking layer. A channel structure may have a cylindrical shape (e.g., a pillar shape). According to some implementations, a semiconductor channel, a tunneling layer, a storage layer and a blocking layer are radially arranged in this order from the center of the pillar toward the outer surface of the pillar. A tunneling layer may include silicon oxide, silicon oxynitride, or any combination thereof. A storage layer may include silicon nitride, silicon oxynitride, or any combination thereof. A blocking layer may include silicon oxide, silicon oxynitride, a high dielectric constant (high-k) dielectric, or any combination thereof. In an example, a memory film may include a composite layer of silicon oxide/silicon oxynitride/silicon oxide (ONO).

Referring back to FIG. 3B, the peripheral circuit may be coupled with the memory cell array through bit line 316, word line 318, source line 314, bottom select gate line 315, and top select gate line 313. The peripheral circuit may include any suitable analog, digital, and mixed-signal circuit for facilitating operation of the memory cell array by applying a voltage signal and/or a current signal to and sensing voltage signal and/or current signal from each target memory cell 306 via bit line 316, word line 318, source line 314, bottom select gate line 315, and top select gate line 313. The peripheral circuit may include various types of peripheral circuits formed with metal-oxide-semiconductor (MOS) technology.

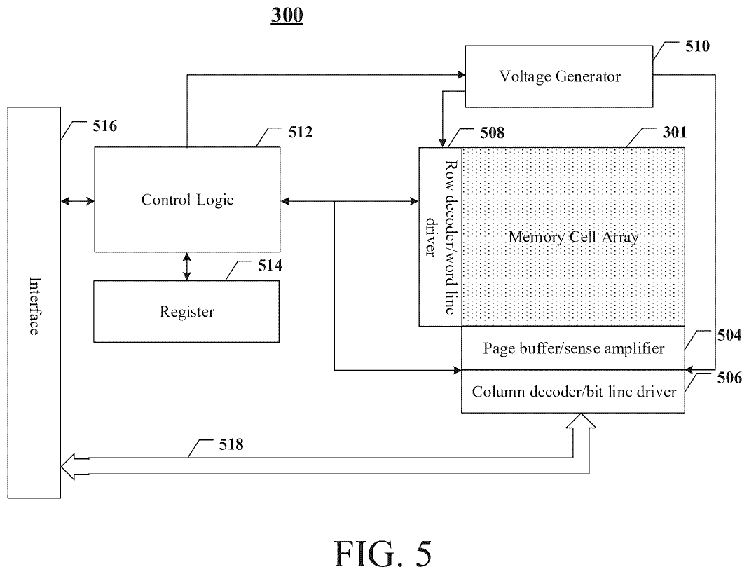

FIG. 5 is a schematic diagram of an example of a memory device comprising a memory cell array and a peripheral circuit according to an example of the present disclosure. For example, FIG. 5 illustrates some examples of peripheral circuits of memory device 300, the peripheral circuit includes page buffer/sense amplifier 504, column decoder/bit line driver 506, row decoder/word line driver 508, voltage generator 510, control logic 512, register 514, interface 516 and data bus 518. It is to be understood that in some examples, additional peripheral circuits not shown in FIG. 5 may also be included.

The page buffer/sense amplifier 504 may be configured to read data from and program (write) data to the memory cell array 301 according to control signals from the control logic 512. In one example, the page buffer/sense amplifier 504 may store program data (written data) to be programmed into the memory cell array 301. In another example, the page buffer/sense amplifier 504 may perform a program verify operation to ensure that data has been correctly programmed into memory cell 306 coupled to selected word line 318. In yet another example, the page buffer/sense amplifier 504 may also sense a low power signal from bit line 316 representing a data bit stored in memory cell 306, and amplify a small voltage swing to a recognizable logic level during a read operation. The column decoder/bit line driver 506 may be configured to be controlled by control logic 512 and to select one or more memory strings 308 through applying a bit line voltage obtained from voltage generator 510.

The row decoder/word line driver 508 may be configured to be controlled by control logic 512 and to select/deselect a memory block of the memory cell array 301 and to select/deselect word line 318 of the memory block. The row decoder/word line driver 508 may also be configured to drive word line 318 with a word line voltage obtained from voltage generator 510. In some implementations, the row decoder/word line driver 508 may also select/deselect and drive the bottom select gate line 315 and top select gate line 313. As described in detail below, the row decoder/word line driver 508 is configured to perform program operations on the memory cells 306 coupled to the selected word line(s) 318. The voltage generator 510 may be configured to be controlled by the control logic 512, and obtain word line voltage (e.g., read voltage, program voltage, pass voltage, channel boost voltage, verify voltage, etc.), bit line voltage and source line voltage to be provided to the memory cell array 301.

The control logic 512 may be coupled to each of other components of the peripheral circuit described above, and configured to control operations of each of the other components of the peripheral circuit. The register 514 may be coupled to the control logic 512 and include status register, command register and address register for storing status information, command operation code (OP code) and command address for controlling operations of each of the peripheral circuits. The interface 516 may be coupled to control logic 512 and act as a control buffer to buffer and relay control commands received from a host (not shown) to control logic 512 and to buffer and relay status information received from the control logic 512 to the host. Interface 516 may also be coupled to column decoder/bit line driver 506 via data bus 518 and act as a data I/O interface and data buffer to buffer and relay data to or from memory cell array 301.

In some examples, the host 108 sends a read command (or a read instruction, a read request) to the memory controller 106 according to the current user command requirement; the memory controller 106 transmits a read control command comprising information such as a logical address to physical address mapping table to the memory device 104 through the interface 516, to control the memory device 104 to perform a read operation on the memory cell corresponding to the corresponding physical address, and the memory device 104 then sends the read data to the memory controller 106 through the interface 516, and the memory controller 106 feeds back the data to the host 108 through an interface such as PCIe or SATA. For example, the memory controller 106 sends the read control command to the control logic of the memory device via the interface 516, and the control logic applies an associated operation voltage to the selected word line or bit line according to an associated physical address, thereby performing a read operation on the corresponding memory cell. According to an associated read voltage mapping table, the control logic may control the voltage generator to generate the associated operation voltage, and then apply it to the word line of corresponding address after decoded by the row decoder, or to the bit line of corresponding address after decoded by the column decoder.

In some examples, when the memory device 104 reads the corresponding memory cell under the control of the memory controller 106, a read error occurs, and in this case, in response to the read operation failure, the memory controller 106 controls the memory (or the error correction module in the memory controller 106) to perform error correction, the error correction mode may include Error Correction Code (ECC).

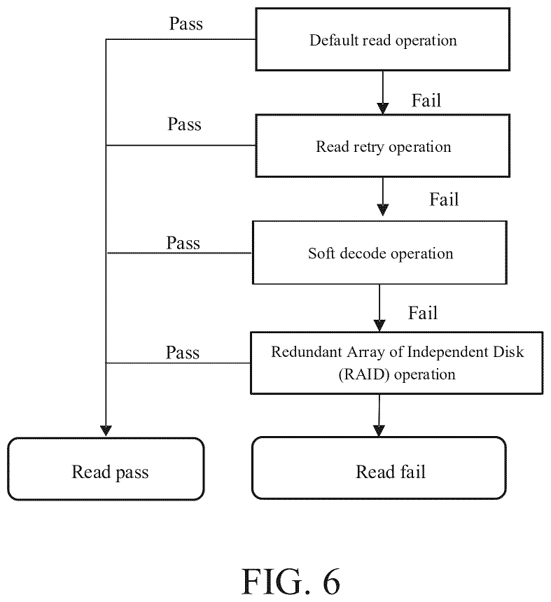

FIG. 6 shows a schematic diagram of an example of a read operation process of a memory system. As shown in FIG. 6, when the memory controller controls the memory device to perform a read operation, a default read operation is firstly performed on the memory cell of a corresponding physical address, a read retry operation is performed after the default read operation fails, a soft decode operation is performed after the read retry operation fails, a redundant array of independent disk (RAID) operation is performed after the soft decode operation fails, the read operation stops after the RAID operation fails, and the read fails due to the failure of error correction, and the memory controller sends a read fail signal to the host 108. The read retry operation and the default read operation may be applied to hard decode.

In some implementations, a read retry operation may be performed by querying a retry table provided by the manufacturer. The essence of the read retry operation is an error correction mechanism, in which a read retry table may provide a reference voltage for reading data. Each memory cell is read again by querying the read retry table and attempting the read voltage deviated from the normal threshold voltage, and together with ECC error correction algorithm for error correction, an attempt to correctly read the data is made. If the incorrectly read data is corrected, stop querying the read retry table. If the incorrectly read data is not corrected, keep querying the read retry table until the entire read retry table is traversed.

In some examples, the memory cell array of the memory device 104 may include a plurality of memory blocks, each memory block includes a plurality of layers of word lines and a plurality of memory cells coupled with each layer of word lines. A plurality of memory cells coupled to a layer of word lines in each memory block may serve as one or more physical pages. Referring to FIG. 3A, a plurality of memory cells coupled to a layer of word lines in a memory block may serve as six physical pages (corresponding to six memory slices), and one of the six memory slices of a layer of word lines may be selected as a selected physical page through an top select gate line. The memory device 104 is capable of performing a program (write) operation on a page level, and programming all memory cells in a selected physical page. The memory block may be a close block or an open block depending on whether all physical pages in the memory block have been programmed.

Due to the influence of the so-called background pattern effect, under the same read condition, for the memory cell in the open block and the memory cell in the close block, due to the influence of factors such as the difference in the total amount of stored charges, the parasitic capacitance, and the charge coupling, the threshold voltage of the memory cell in the open block may be offset compared to the threshold voltage of the memory cell in the close block. For example, in a read operation, a threshold voltage of a memory cell in a close block is higher than a threshold voltage of a memory cell in an open block under the same read condition. The memory device 104 may set its internal read condition (e.g., default read voltage) according to the close block condition, and when read the memory cell in the open block, applying an internal read condition to the open block may cause more read errors due to the negative shifted threshold voltage in the open block.

In some examples, the memory device 104 may read the data of the memory cells in the close block according to the default read voltage, and may read the data of the memory cells in the close block according to the offset read voltage having the offset relative to the default read voltage to reduce read errors, e.g., reduce fail bit.

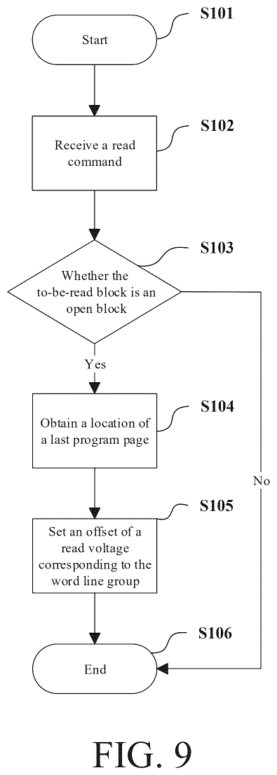

FIG. 9 is a first schematic diagram of an example of a process of setting an offset read voltage of a memory device according to the present disclosure. Referring to FIG. 9, in order to cover a read operation in all open block scenarios, a plurality of layers of word lines of an open block need to be divided into a plurality of word line groups, each word line group has a corresponding offset read voltage, and the memory device is configured to set an offset read voltage. The example of the process includes performing the following operations: operation S101, starting to set an offset read voltage; operation S102, receiving a read command; operation S103, retrieving the to-be-read block to be read according to the read command and determining whether the to-be-read block is an open block; operation S104, obtaining a location of a last program page according to the to-be-read block being an open block; operation S105, setting an offset of a read voltage corresponding to the word line group according to the word line group to which the last program page belongs; and operation S106, ending the offset read voltage setting, and the offset read voltage is a difference between the default read voltage and the offset.

With the increasing storage capacity of the memory device and higher integration density, for example, the increasing number of layers of stacked word lines (corresponding to the number of stacked layers of memory cells) of the NAND flash memory, the reading of the memory cells in the open block is increasingly affected by the background pattern effect. In order to cover the read operation in all open block scenarios, a plurality of layers of word lines of an open block need to be divided into a plurality of word line groups. The increasing number of word line groups in the open block make the memory device increasingly complex in processing the read operation logic of the open block, and the corresponding offset read voltage table (comprising the mapping relationship between the word line group and the offset of the read voltage) becomes larger. Thus, finding a way to simply handle read operations of open blocks appears exceptionally important.

According to one or more of the foregoing problems, in a first aspect, an example of the present disclosure provides a memory device. The memory device comprises: a memory cell array including a plurality of memory blocks, and a peripheral circuit coupled with the memory cell array and configured to: perform a first read operation on a memory cell included in an edge page in a to-be-read block of the plurality of memory blocks using a first offset read voltage according to the to-be-read block being an open block; the first offset read voltage has a first offset relative to a first read voltage; and the first read voltage is a read voltage corresponding to the first read operation in default read voltages of the to-be-read block.

In the examples of the present disclosure, the first read operation is performed on the memory cell included in the edge page using the first offset read voltage according to the to-be-read page being an edge page of an open block, so that the first read operation logic of processing the open block by the peripheral circuit of the memory device is simplified, which facilitates reducing the complexity of the first read operation processing, for example, facilitates reducing the memory space occupied by the first offset table (including the mapping relationship between the first offset and the edge page) corresponding to the first offset read voltage, which facilitates reducing the fail bit count of the first read operation. According to the example of the present disclosure, a plurality of layers of word lines of an open block do not need to be divided into a plurality of word line groups, thereby avoiding the case where the increasing number of word line groups in the open block makes the memory device increasingly complex in processing the read operation logic of the open block.

Here and below, the memory device may be understood with reference to the related description of the memory device 104 shown in FIG. 1, FIG. 2A, and FIG. 2B, and the memory cell array and the peripheral circuit may be respectively understood with reference to the related descriptions of the memory cell array and the peripheral circuit shown in FIG. 3B and FIG. 5.

In some examples, the memory device includes a three-dimensional NAND type memory. The memory cells of the three-dimensional NAND memory cells include a single-level cell SLC, a multi-level cell MLC, a trinary-level cell TLC, a quad-level cell QLC. One memory cell from SLC to QLC can store 1, 2, 3, and 4 bits of data, respectively, and correspondingly, the voltage states of the memory cells of the three-dimensional NAND memory cells are 2, 4, 8, and 16 respectively. Since the number of voltage states of the memory cell from the SLC mode to the QLC mode of the memory device changes from 2 to 16, and the number of different voltage states is increasing and become more difficult to control, the time for programming is longer, the read/write speed is reduced, the voltage state stability is reduced, and correspondingly, the theoretical program-erase cycle number is reduced. For example, the theoretical program-erase cycle number (or the preset program-erase cycle number) of the memory device in SLC, MLC, TLC, QLC mode may be 100 thousand, 3-10 thousand, 500-1000, or 150, respectively. Although the memory cells of some of the NAND memory cells may still be usable over the theoretical program-erase cycle number, the stored bit data may be unstable.

In some examples, the memory cell array includes memory cells storing N bits, the N memory bits respectively correspond to N pages, the memory cell of N bits read their N bits of stored data through the Q level read voltages; N and Q are all integers greater than 1, and Q=2^{N}−1. The default read voltages of the memory device corresponding to the SLC, MLC, TLC and QLC modes are a 1-level read voltage, a 3-level read voltage, a 7-level read voltage, and a 15-level read voltage, respectively.

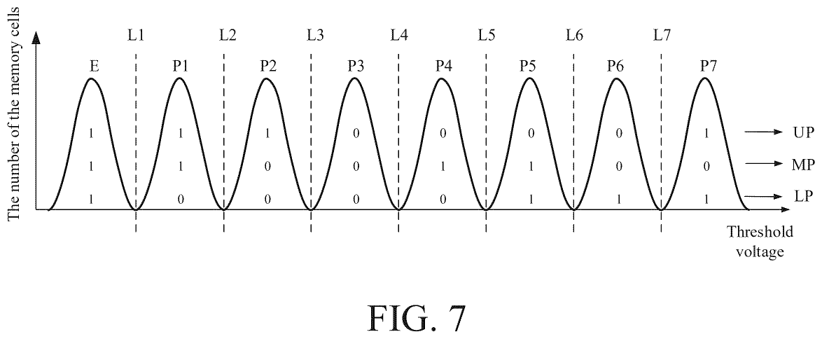

FIG. 7 is a schematic diagram of threshold voltage distribution corresponding to a memory cell comprising 3 memory bits according to an example of the present disclosure. Referring to FIG. 7, taking an example in which a default read voltage of a memory device corresponding to a TLC mode is a 7-level read voltage for description, when a number of memory bits of a memory cell includes three bits, the corresponding memory states includes a zeroth state to a seventh state, the eight states includes a zeroth state (also referred to as an erase state) E, a first state (also referred to as a first memory state) P1, a second state (also referred to as a second memory state) P2 . . . , a seventh state (also referred to as a seventh memory state) P7, and the binary data corresponding to the 8 states are 111, 110, 100, 000, 010, 011, 001, and 101, respectively. Correspondingly, the memory device includes three pages, namely lower page (LP), middle page (MP), and upper page (UP), respectively.

The three-bit memory cells read the stored data with three bits and eight states by a 7-level read voltage (the first level read voltage L1, the second level read voltage L2, the third level read voltage L3, the fourth level read voltage L4, the fifth level read voltage L5, the sixth level read voltage L6, and the seventh level read voltage L7 shown in FIG. 7). Each page corresponds to a multi-level read voltage, the binary data corresponding to the lower page is 10000111, and reading the lower page needs the corresponding first level read voltage L1 and the fifth level read voltage L5. The binary data corresponding to the middle page is 11001100, and reading the middle page needs the corresponding second level read voltage L2, the fourth level read voltage L4, and the sixth level read voltage L6. The binary data corresponding to the upper page is 11100001, and reading the upper page needs the corresponding third level read voltage L3 and the seventh level read voltage L7.

In the TLC mode of the memory device, the default read voltage is a 7-level read voltage, which includes the first level read voltage L1 and the fifth level read voltage L5 corresponding to the reading of the lower page, the second level read voltage L2, the fourth level read voltage L4, and the sixth level read voltage L6 corresponding to the reading of the middle page, and the third level read voltage L3 and the seventh level read voltage L7 corresponding to the reading of the upper page. The first read voltage is one of the 7-level read voltages, for example, the first read operation corresponds to the partial binary data of the lower page read by the first level read voltage L1, the first read voltage is the first level read voltage L1, and the first offset read voltage is the difference between the first level read voltage L1 and the first offset.

In some examples, a number of memory bits stored in the memory cell is N, and the memory cell has 2^{N} memory states; 2^{N} memory states include an erase state and 2^{N}−1 non-erase states; wherein N is a positive integer; the default read voltages include 2^{N}−1 read voltages from a first level read voltage to a (2^{N}−1)-th level read voltage; the first read voltage is one of 2^{N}−1 read voltages; the first offset is associated with the first read voltage.

In some examples, the first offset is determined to be the first value according to the first read voltage being a read voltage of the 2^{N}−1 read voltages; and the first offset is determined to be the second value different from the first value according to the first read voltage being another read voltage of the 2^{N}−1 read voltages which is different from the read voltage. For example, in the read operation corresponding to the reading of the lower page in the TLC mode of the memory device, the first read voltage is the first level read voltage L1, the first offset is the first value, and the first offset read voltage is the difference between the first level read voltage L1 and the first value of the first offset; in the read operation corresponding to the reading of the middle page, the first read voltage is the second level read voltage L2, the first offset is the second value, and the first offset read voltage is the difference between the second level read voltage L2 and the second value of the first offset, wherein the second value is less than the first value.

In some examples, the first offset is not associated with the first read voltage, and the values of the first offset are the same according to the first read voltage being different ones of the 2^{N}−1 read voltages. For example, in the TLC mode of the memory device, the default read voltage is the first level read voltage L1 to the seventh level read voltage L7, and the first offset read voltage is the difference between one of the first level read voltage L1 to the seventh level read voltage L7 and the first offset.

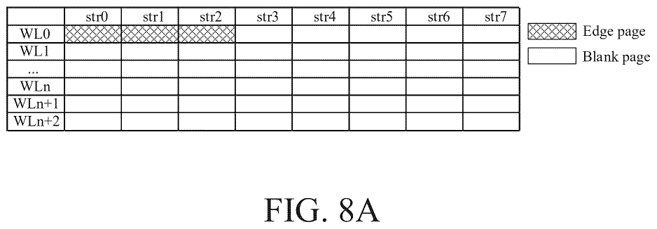

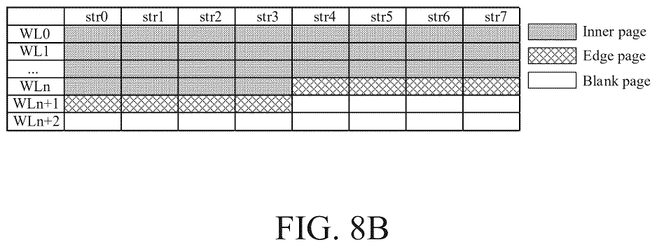

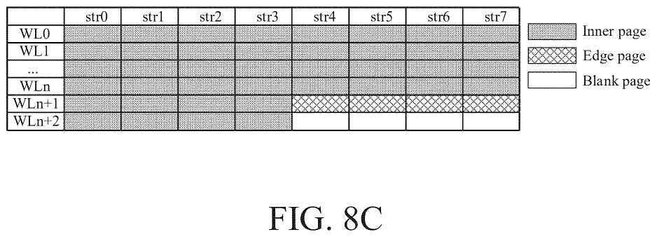

FIG. 8A is a schematic diagram of an open block having an edge page of a memory device according to the present disclosure. FIG. 8B is a schematic diagram of an open block having an edge page and an inner page of a memory device according to the present disclosure. FIG. 8C is another schematic diagram of an open block having an edge page and an inner page of a memory device according to the present disclosure.

Referring to FIG. 8A, FIG. 8B, and FIG. 8C, in some examples, the open block includes at least one blank page including memory cells that are not programmed and at least one program page including memory cells that have been programmed; wherein the at least one program page includes an edge page which is adjacent to one of the at least one blank page in a stacking direction of the to-be-read block. The stacking direction of the to-be-read block may be understood as an extending direction of a memory string or a stacking direction of a plurality of word line.

The states of the memory cells included in the blank page are all an erase state. Not all the states of the memory cells included in the program page (or the write page) are the erase state (at least part of which are program state). The edge page may represent a word line in the program page adjacent to the blank page in the stacking direction of the to-be-read block.

In some examples, the close block includes a program page and does not include a blank page, a memory cell included in the program page has been programmed, and the program page does not include an edge word line. Since the open block has an edge page, for example, there is a case in which the blank page is adjacent to the program page. Because there is a charge difference between the memory cell included in the program page and the memory cell included in the blank page adjacent to the program page, the threshold voltage of the memory cell in the open block has a more complex threshold voltage offset situation than the threshold voltage of the memory cell in the close block, and different locations of the program page and the blank page in the memory block make the threshold voltage offset situation more complex.

For example, with reference to FIG. 3C, FIG. 8A, FIG. 8B, and FIG. 8C, the open block includes a memory string array coupled with a word line WL0, a word line WL1, . . . a word line WLn, a word line WLn+1, and a word line WLn+2 that are stacked; a memory string in which the memory cell coupled with each word line is located includes a memory slice str0, a memory slice str1, a memory slice str2, a memory slice str3, a memory slice str4, a memory slice str5, a memory slice str6, and a memory slice str7 that may be selected by respective top select gate lines; and a page (or a so-called physical page) may be located by each word line with the memory slice str0 to the memory slice str7 respectively. For example, the page PGn0, the page PGn1, the page PGn2, the page PGn3, the page PGn 4, the page PGn5, the page PGn 6 and the page PGn7 may be located by the word line WLn with the memory slice str0 to the memory slice str7 respectively, for example, the memory cells coupled with each word line are divided into pages PGn0 to PGn7 which can be independently read or programmed. The peripheral circuit is configured to activate the selected memory slice through the selected top select gate line in the selected word line during a read and program operation. For example, the peripheral circuit is configured to activate the selected memory slice str0 through the selected top select gate line TSG0 in the selected word line WL0 during a read or program operation, the word line WL0 and the memory slice str0 locate one page PG00, and the memory cells coupled to the page PG00 are read or programmed. In practical applications, the number of word lines included in one memory block may be adjusted according to actual conditions, such as 16, 32, 64, and 128, and the like. In practical applications, the number of pages included in the memory cell coupled with a word line may be adjusted according to actual conditions, such as 2, 4, 6, 8, 10, 12, and the like.

For example, in a program operation, a top word line or a bottom word line may be used as a starting program word line; wherein the top word line and the bottom word line are respectively located at two opposite ends of the memory string, the top word line may be located at one end relatively close to the bit line, and the bottom word line may be located at one end relatively far away from the bit line; in a program word line, the left end memory string or the right end memory string may be used as the starting program page of the program word line; wherein the top word lines of the left end memory string and the right end memory string are respectively located at two opposite ends of the column of memory strings connected to the bit line. An index may be set for the pages in the memory block, when one memory block includes 8 memory slices, the memory cell coupled with one word line includes 8 pages which are sequentially numbered according to the program order (the order in which the program voltage is applied) of the pages, with the index of the start page PG00 is 0, and the index of the last page PG(n+2)7 is (8*(n+3)−1). For example, when n is 5, the memory block includes 8 word lines comprising the stacked word line WL0 to the word line WL7, and the memory block includes 64 pages whose indexes are 0 to 63; when n is 13, the memory block includes 16 word lines comprising the stacked word line WL0 to the word line WL15, and the memory block includes 128 pages whose indexes are 0 to 127, and when n is 125, the memory block includes 128 word lines comprising the stacked word lines WL0 to WL127, and the memory block includes 1024 pages whose indexes are 0 to 1023; or, the memory block includes other numbers of pages that are indexed.

For example, in a program writing, the writing may start from a page with an index of 0 so that a single memory block may be fully written to reduce the addressing pressure, and this is merely for physical addresses, while logical addresses are not restricted in terms of their continuity. Referring to FIG. 8B and FIG. 8C, for a case in which the memory block is an open block, the program pages of the open block may correspond to continuous physical addresses, a stripe of pages in the program pages adjacent to the unprogrammed blank pages along the stacking direction of the word lines (or the extending direction of the memory strings) may be denoted as edge pages, and the rest of the program pages are denoted as inner pages. Optionally, the program page of the open block includes an edge page and does not include an inner page (as shown in FIG. 8A), and the unprogrammed blank pages of the open block may be denoted as blank pages. Taking an example in which memory cells coupled with one word line include 8 pages selected by corresponding top select gate lines and the memory block includes 128 pages with indices 0-127 for description: referring to FIG. 8A, the program pages are pages with indices 0-2, where there is no inner page, the edge pages are pages with indices 0-2, and the blank pages are pages with indices 3-127; referring to FIG. 8B, the program pages are pages with indices 0-115, where the inner pages are pages with indices 0-107, the edge pages are pages with indices 108-115, and the blank pages are pages with indices 116-127; referring to FIG. 8C, the program pages are pages with indices 0-123,where the inner pages are pages with indices 0-115 and pages with indices 120-123, the edge pages are pages with indices 116-119, and the blank pages are pages with indices 124-127.

In some examples, the edge pages are adjacent to the blank pages along the stacking direction of word lines, and the edge pages are most affected by the blank pages, for example, an offset value of the threshold voltage of a memory cell in the edge page is greater than an offset value of the threshold voltage of a memory cell in the inner page.

In some examples, the peripheral circuit may be configured to generate an edge page according to the location of the last program page in the open block or its index. Referring to FIG. 8A, the last program page is a page with index 2, and the edge pages are pages with indices 0-2; referring to FIG. 8B, the last program page is a page with index 115, and the edge pages are pages with indices 108-115; or referring to FIG. 8C, the last program page is a page with index 123, and the edge page are pages with indices 116-119.

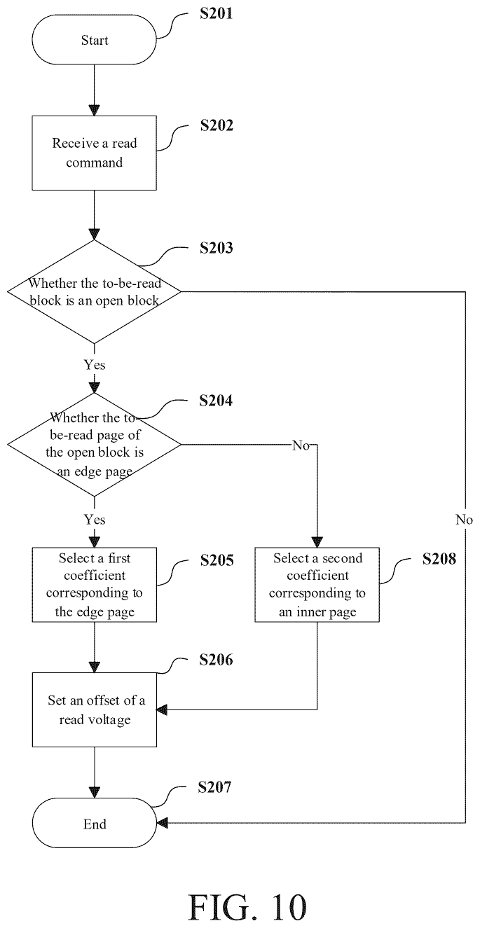

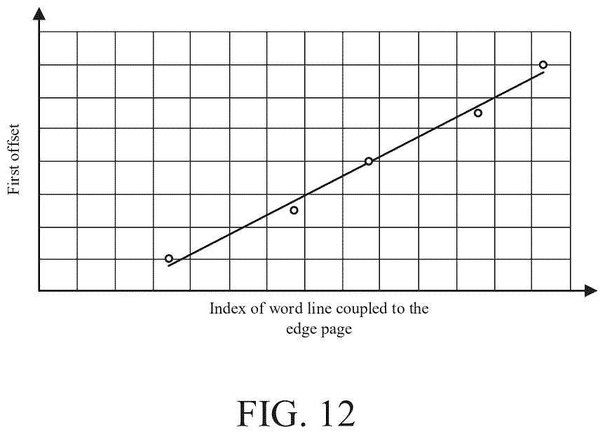

FIG. 10 is a second schematic diagram of an example of a process of setting an offset read voltage of a memory device according to the present disclosure. FIG. 12 is a schematic diagram of a relationship between an index of a word line coupled to an edge page in an open block of a memory device and a voltage value of a first offset according to the present disclosure.

Referring to FIG. 10, the peripheral circuit is further configured to perform the following operations: operation S201, starting to set an offset read voltage; operation S202, receiving a read command; operation S203, retrieving the to-be-read block to be read according to the read command and determining whether the to-be-read block is an open block; operation S204, determining whether the to-be-read page of the open block is an edge page according to the to-be-read block being an open block; operation S205, selecting a first coefficient corresponding to the edge page according to the to-be-read page of the open block being an edge page; operation S206, setting an offset of the read voltage according to the first coefficient; and operation S207, ending the offset read voltage setting, and performing a read operation on the memory cell included with the to-be-read page using the offset read voltage.

With reference to FIG. 10 and FIG. 12, in some examples, the peripheral circuit is configured to perform the following operations: operations S205 and S206: determining the first offset according to a number of program pages and a first coefficient; the first offset is positively correlated with the number of program pages and is negatively correlated with the first coefficient; and obtaining the first offset read voltage according to a difference between the first read voltage and the first offset.

In some examples, the peripheral circuit may be configured to generate the number of program pages according to the location of the last program page in the open block. The location of the last program page may be generated according to the index of the last program page, referring to FIG. 8A, the last program page is a page with index 2, and the number of program pages is 3, or referring to FIG. 8B, the last program page is a page with index 115, and the number of program pages is 116.

In some examples, the first coefficient may be an empirical value, or may be a default value configured when the memory device leaves the factory, and the default value is obtained by performing a large number of simulation experiments before the memory device leaves the factory; the first coefficient may be a default value configured when the memory device leaves the factory, and the default value is obtained by performing a large number of simulation experiments before the memory device leaves the factory. In some examples, the first coefficient ranges from 5 to 25, preferably, the first coefficient ranges from 10 to 20, and for example, the first coefficient is 11, 12, 13, 14, 15, 16, 17, 18 or 19.

Referring to FIG. 8B, FIG. 10, and FIG. 12, in some examples, the peripheral circuit may be configured to obtain the value of the first offset based on the value of the initial offset plus the ratio between the number of program pages and the first coefficient. For example, if the value of the initial offset is initial RV, the number of program pages is 116, the first coefficient is 16, the value of the first offset is initial RV+116/16, in units of DAC, for example, the first offset is (initial RV+116/16) DAC. It can be understood that the physical meaning of the first coefficient is that each time the number of program pages is increased by 16, then the first offset is increased by 1 DAC. The initial offset may be a default value configured when the memory device leaves the factory, and the default value is obtained by performing a large number of simulation experiments before the memory device leaves the factory. In some examples, a minimum unit of setting the first offset is 1 DAC (for example, a conversion relationship between a DAC and a millivolt (mv) is 1 DAC=10 mv), so the setting of the first offset is finer, which facilitates reducing a fail bit count of the first read operation.

In an optional example, the peripheral circuit may be configured to determine the first offset according to the index of the word line coupled with the last program page in the open block and the first coefficient. Referring to FIG. 8A, the index of the word line WL0 coupled to the last program page is 0. Referring to FIG. 8B, the index of the word line WLn+1 coupled to the last program page is n+1. Referring to FIG. 8C, the index of the word line WLn+2 coupled to the last program page is n+2. For example, taking FIG. 8B as an example, the value of the initial offset is initial RV, the index of the word line WLn+1 coupled to the last program page is 116, the first coefficient is 16, then the value of the first offset is initial RV+116/16, in units of DAC, for example, the first offset is (initial RV+116/16) DAC. It can be understood that the physical meaning of the first coefficient is that each time the index of the word line coupled to the last program page is increased by 16, and the first offset is increased by 1 DAC.

In some examples, the first offset table includes a number of program pages and a mapping relationship between the first coefficient and the first offset. The peripheral circuit may be configured to manage the first offset table, and obtain a first offset read voltage according to a difference between the first read voltage and the first offset, the first offset read voltage is configured to read the program page of the to-be-read block. In this way, the first read operation is performed on the memory cell included in the edge page in the open block, and the first offset corresponding to performing the first read operation may be obtained based on the number of the program pages and the first offset table.

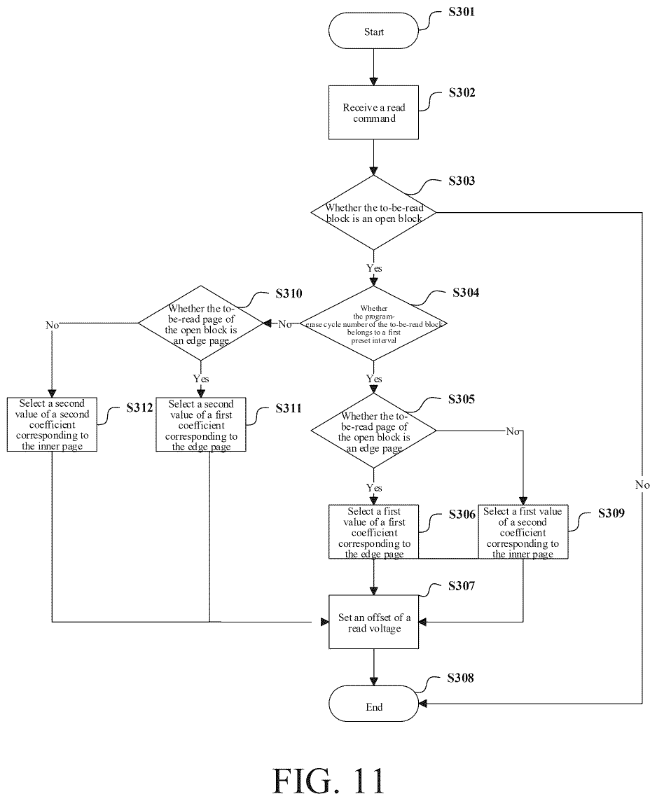

FIG. 11 is a third schematic diagram of an example of a process of setting an offset read voltage of a memory device according to the present disclosure.

Referring to FIG. 11, in some examples, the peripheral circuit is further configured to: perform a first correction on the first coefficient according to a program-erase cycle number corresponding to the to-be-read block being in a first preset interval of a plurality of preset intervals, and determine that the first coefficient is a first value; and perform a second correction on the first coefficient according to the program-erase cycle number corresponding to the to-be-read block being in a second preset interval of the plurality of preset intervals which is different from the first preset interval, and determine that the first coefficient is a second value different from the first value; wherein each preset interval of the plurality of preset intervals includes at least one program-erase cycle number, and an average value of the preset interval is an average value of respective program-erase cycle numbers in the preset interval.

The first preset interval and the second preset interval are two range intervals that are different and have no overlap within a range of theoretical program-erase cycle numbers of the product of the memory device. For example, the first preset interval may be understood as a range interval of program-erase cycle number corresponding to the begin of life (BOL) of the memory device, and the second preset interval may be understood as a range interval of program-erase cycle number corresponding to the end of life (EOL) of the memory device. For example, the theoretical program-erase cycle number of the memory device in the MLC mode is 3000 times, the first preset interval may be an interval range of 0 to 1000 times, the second preset interval may be an interval range of 2000 to 3000 times, or the first preset interval may be an interval range of 100 to 800 times, and the second preset interval may be an interval range of 1500 to 2800 times.

In some examples, considering different specific scenarios of the memory device, the values of the first coefficients may be different. When the program-erase cycle number is small, for example, in the begin of life reliability scenario of the memory device, and when the program-erase cycle number increases, for example, in the end of life reliability scenario of the memory device, the values of the first coefficient are different.

In some examples, different lifecycle (e.g., BOL/EOL) reliability scenarios of the memory device are associated with a first offset read voltage of the memory device, and generation of respective first offset read voltages for different lifecycles which the memory device is in can reasonably consider different lifecycle (e.g., BOL/EOL) reliability scenario requirements of the memory device. For example, in a BOL reliability scenario of the memory device, the first coefficient is a first value, and in an EOL reliability scenario of the memory device, the first coefficient is a second value, wherein the first value is greater than the second value (for example, the first value is 18 and the second value is 14).

Referring to FIG. 11, in some examples, the peripheral circuit is further configured to perform the following operations: operation S301, starting to set an offset read voltage; operation S302, receiving a read command; operation S303, retrieving the to-be-read block to be read according to the read command and determining whether the to-be-read block is an open block; operation S304, according to the to-be-read block being an open block, determining whether the program-erase cycle number corresponding to the to-be-read block belongs to a first preset interval; operation S305, according to the program-erase cycle number corresponding to the to-be-read block belongs to the first preset interval, determining whether the to-be-read page of the open block is an edge page; operation S306, selecting a first value of the first coefficient corresponding to the edge page according to the to-be-read page of the open block being an edge page; operation S307, setting an offset of the read voltage according to the first value of the first coefficient; and operation S308, ending the offset read voltage setting, and performing a read operation on the memory cell included in the edge page using the offset read voltage.

Referring to FIG. 11, in some examples, the peripheral circuit is further configured to perform the following operations: operation S301, starting to set an offset read voltage; operation S302, receiving a read command; operation S303, retrieving the to-be-read block to be read according to the read command and determining whether the to-be-read block is an open block; operation S304, according to the to-be-read block being an open block, and determining whether the program-erase cycle number corresponding to the to-be-read block belongs to a first preset interval; operation S310, according to the program-erase cycle number corresponding to the to-be-read block does not belong to the first preset interval, for example, the program-erase cycle number corresponding to the to-be-read block belongs to the second preset interval, and whether the to-be-read page of the open block is an edge page; operation S311, selecting a second value of the first coefficient corresponding to the edge page according to the to-be-read page of the open block being an edge page; operation S307, setting an offset of the read voltage according to the second value of the first coefficient; and operation S308, ending the offset read voltage setting, and performing a read operation on the memory cell included in the to-be-read page using the offset read voltage.

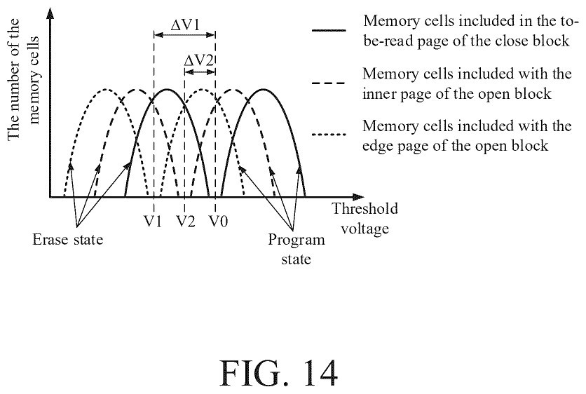

FIG. 14 is a diagram of an example of a threshold voltage distribution in a first read operation and a second read operation of a memory device according to the present disclosure.

Referring to FIG. 8B, FIG. 10, and FIG. 14, in some examples, the open block includes a plurality of program pages which include an edge page and an inner page; the peripheral circuit is further configured to: perform a second read operation on a memory cell included in the inner page using a second offset read voltage; the second offset read voltage has a second offset relative to the second read voltage; the second read voltage is a read voltage corresponding to the second read operation in the default read voltages; wherein the second offset is less than the first offset.

Referring to FIG. 14, in a read operation in which a program state and an erase state are distinguished, a read voltage V0 in the default read voltages is used to perform a read operation on a memory cell included in a page of the close block; a first offset read voltage V1 is used to perform a first read operation on a memory cell included in an edge page of the open block, and the first offset read voltage V1 has a first offset ΔV1 relative to a read voltage V0 of the default read voltages; a second offset read voltage V2 is used to perform a second read operation on a memory cell included in an inner page of the open block, and the second offset read voltage V2 has a second offset ΔV2 relative to a read voltage V0 of the default read voltages; wherein the second offset ΔV2 is less than the first offset ΔV1.

In some examples, the default read voltages include 2^{N}−1 read voltages from the first level read voltage to the (2^{N}−1)th level read voltage; the second read voltage is one of the 2^{N}−1 read voltages, wherein N is a natural number. In some examples, a case where there is an association or there is no association between the second offset and the second read voltage may be understood with reference to the foregoing case in which there is an association or there is no association between the first offset and the first read voltage, and details are not described herein again.

In the example of the present disclosure, a plurality of layers of word lines of an open block do not need to be divided into a plurality of word line groups, and the first read operation is performed on the memory cell included in the edge page using the first offset read voltage, and the second read operation is performed on the memory cell included in the inner page using the second offset read voltage, so that the first read operation logic of processing the open block by the peripheral circuit is simplified, which facilitates reducing the complexity of the first read operation processing, for example, facilitates reducing the memory space occupied by the corresponding first offset table (comprising the mapping relationship between the first offset and the edge page) and the second offset table (comprising the mapping relationship between the second offset and the inner page), and facilitates reducing the fail bit count of the first read operation and the second read operation.

Referring to FIG. 10, in some examples, the peripheral circuit is further configured to perform the following operations: S201, starting to set an offset read voltage; S202, receiving a read command; S203, retrieving the to-be-read block to be read according to the read command, whether the to-be-read block is an open block; S204, according to the to-be-read block being an open block, and according to whether the to-be-read page of the open block is an edge page; S205, selecting a second coefficient corresponding to the inner page according to the to-be-read page of the open block being not an edge page, for example, the to-be-read page is an inner page; S206, setting an offset of the read voltage according to the second coefficient; and S207, ending the offset read voltage setting, and performing a read operation on the memory cell included in the to-be-read page using the offset read voltage.

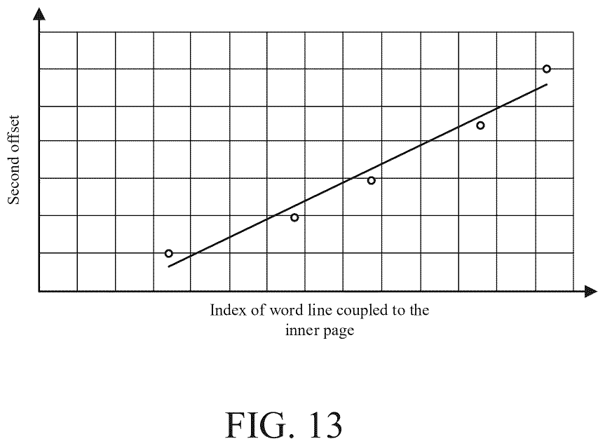

FIG. 13 is a schematic diagram of a relationship between an index of a word line coupled to an inner page in an open block of a memory device and a voltage value of a second offset according to the present disclosure.

Referring to FIG. 10 and FIG. 13, in some examples, the peripheral circuit is configured to perform the following operations: S208 and S206: determining the second offset according to the number of program pages and a second coefficient; the second offset is positively correlated with the number of program pages and is negatively correlated with the second coefficient; and obtaining the second offset read voltage according to a difference between the second read voltage and the second offset.

In the example of the present disclosure, the contents related to the number of program pages may be understood with reference to the foregoing content of the first coefficient, and details are not described herein again.

In some examples, the second coefficient may be an empirical value; or may be a default value configured when the memory device leaves the factory, and the default value is obtained by performing a large number of simulation experiments before the memory device leaves the factory; the second coefficient may be a default value configured when the memory device leaves the factory, and the default value is obtained by performing a large number of simulation experiments before the memory device leaves the factory. In some examples, the second coefficient ranges from 10 to 30, preferably, the second coefficient ranges from 15 to 25, and for example, the second coefficient is 16, 17, 18, 19, 20, 21, 22, 23 or 24. In some examples, the value of the second coefficient is greater than the value of the first coefficient. For example, the second coefficient is 20, and the first coefficient is 16.

Referring to FIG. 8B, FIG. 10, and FIG. 13, in some examples, the peripheral circuit may be configured to obtain the value of the second offset based on the value of the initial offset plus the ratio between the number of program pages and the second coefficient. For example, if the value of the initial offset is initial RV, the number of program pages is 116, the second coefficient is 20, the value of the second offset is initial RV+116/20, in units of DAC, for example, the second offset is (initial RV+116/20) DAC. It can be understood that the physical meaning of the second coefficient is that each time the number of program pages is increased by 20, then the second offset is increased by 1 DAC. A minimum unit of setting the second offset is 1 DAC, and a conversion relationship between a DAC and a millivolt (mv) may be 1 DAC=10 mv. The content related to the initial offset may be understood with reference to the foregoing content of first coefficient, and details are not described herein again.

In some examples, the second offset table includes a number of program pages and a mapping relationship between the second coefficient and the second offset. The peripheral circuit may be configured to manage a second offset table, and obtain a second offset read voltage according to a difference between the second read voltage and the second offset, and the second offset read voltage is used to read the memory cell coupled to the program page of the to-be-read block.

Referring to FIG. 11, in some examples, the peripheral circuit is further configured to: perform a first correction on the second coefficient according to a program-erase cycle number corresponding to the to-be-read block being in a first preset interval of a plurality of preset intervals, and determine that the second coefficient is a first value; and perform a second correction on the second coefficient according to the program-erase cycle number corresponding to the to-be-read block being in a second preset interval of the plurality of preset intervals which is different from the first preset interval, and determine that the second coefficient is a second value different from the first value; wherein each preset interval of the plurality of preset intervals includes at least one program-erase cycle number, and an average value of the preset interval is an average value of respective program-erase cycle numbers in the preset interval.

In the example of the present disclosure, related descriptions of the first preset interval and the second preset interval may refer to the foregoing examples, and details are not described herein again.

In some examples, different lifecycle (e.g., BOL/EOL) reliability scenarios of the memory device are associated with a second offset read voltage of the memory device, and generation of respective second offset read voltages for different lifecycles which the memory device is in can reasonably consider different lifecycle (e.g., BOL/EOL) reliability scenario requirements of the memory device. For example, in a BOL reliability scenario of the memory device, the second coefficient is a first value, and in an EOL reliability scenario of the memory device, the second coefficient is a second value, wherein the first value is greater than the second value (for example, the first value is 22 and the second value is 18).

Referring to FIG. 11, in some examples, the peripheral circuit is further configured to perform the following operations: operation S301, starting to set an offset read voltage; operation S302, receiving a read command; operation S303, retrieving the to-be-read block to be read according to the read command and determining whether the to-be-read block is an open block; operation S304, determining whether the program-erase cycle number corresponding to the to-be-read block belongs to a first preset interval according to the to-be-read block being an open block; operation S305, determining whether the to-be-read page of the open block is an edge page according to the program-erase cycle number corresponding to the to-be-read block belonging to a first preset interval; operation S309, selecting a first value of the second coefficient corresponding to the inner page according to the to-be-read page of the open block not being an edge page, for example, the to-be-read page of the open block is an inner page; operation S307, setting an offset of the read voltage according to the first value of the second coefficient; and operation S308, ending the offset read voltage setting, and performing a read operation on the memory cell included in the to-be-read page using the offset read voltage.

Referring to FIG. 11, in some examples, the peripheral circuit is further configured to perform the following operations: operation S301, starting to set an offset read voltage; operation S302, receiving a read command; operation S303, retrieving the to-be-read block to be read according to the read command and determining whether the to-be-read block is an open block; operation S304, determining whether the program-erase cycle number corresponding to the to-be-read block belongs to a first preset interval according to the to-be-read block being an open block; operation S310, determining whether the to-be-read page of the open block is an edge page according to the program-erase cycle number corresponding to the to-be-read block not belonging to the first preset interval, for example, the program-erase cycle number corresponding to the to-be-read block belonging to the second preset interval; operation S312, selecting a second value of the second coefficient corresponding to the inner page according to the to-be-read page of the open block being an edge page, for example, the to-be-read page of the open block is an inner page; operation S307, setting an offset of the read voltage according to the second value of the second coefficient; and operation S308, ending the offset read voltage setting, and performing a read operation on a plurality of memory cells coupled to the program page using the offset read voltage.

Referring to FIG. 11, in some examples, the peripheral circuit is further configured to: define the plurality of preset intervals according to a preset program-erase cycle number of the memory device, the plurality of preset intervals comprise M intervals from a first interval to a M-th interval; wherein a number of the M intervals is positively correlated with a magnitude of the preset program-erase cycle number; wherein M is a positive integer and M≥2.

For example, the preset program-erase cycle number of the memory device is defined as three consecutive preset intervals, the three preset intervals are the first preset interval, the third preset interval, and the second preset interval that are consecutive. The interval value of the first preset interval, the interval value of the third preset interval, and the interval value of the second preset interval may be the same or different; wherein the first preset interval may be understood as the range interval of the program-erase cycle number corresponding to the BOL of the memory device, the second preset interval may be understood as the range interval of the program-erase cycle number corresponding to the EOL of the memory device, and the third preset interval may be understood as the range interval of the program-erase cycle number corresponding to the middle of life (MOL) of the memory device.

In some examples, different lifecycle (for example, BOL/MOL/EOL) reliability scenarios of the memory device are associated with a first offset read voltage or a second offset read voltage of the memory device, and generation of respective first offset read voltages or a second offset read voltages for different lifecycles which the memory device is in can reasonably consider different lifecycle (e.g., BOL/MOL/EOL) reliability scenario requirements of the memory device. For example, in a BOL reliability scenario of the memory device, the first coefficient is 18, in a MOL reliability scenario of the memory device, the first coefficient is 16, and in an EOL reliability scenario of the memory device, the first coefficient is 14.

Referring to FIG. 10 and FIG. 11, in some examples, the peripheral circuit is further configured to: determine the first offset or the second offset according to additional information; wherein the additional information includes a retention state or an interference state of the data stored in a memory cell included in the edge page or the inner page.

In some examples, different states (the retention state or the interference state) of the stored data of the memory device is associated with the first offset read voltage or the second offset read voltage of the memory device, and generation of respective first offset read voltages or second offset read voltages for different states of the stored data of the memory device is can reasonably consider the reliability scenario requirements of different states of the stored data of the memory device. For example, in a read operation, when data stored in a plurality of memory cells coupled to a to-be-read word line (select word line) in an open block of the memory device is in a retention state, the first coefficient is set to a third value; when data stored in a plurality of memory cells coupled to a to-be-read word line (select word line) in an open block of the memory device is in an interference state, the first coefficient is set to a fourth value; wherein the third value is different from the fourth value, and the first offset read voltages generated according to the third value and the fourth value are different according to the distribution.

Referring to FIG. 10 and FIG. 11, in some examples, the peripheral circuit is further configured to: perform a third read operation on a memory cell included in a page in the to-be-read block using a third read voltage according to the to-be-read block of the plurality of memory blocks being a close block; the third read voltage is a read voltage corresponding to the third read operation in the default read voltages; and memory cells included in any page of the close block have been programmed.

In some examples, the default read voltages include 2^{N}−1 read voltages from a first level read voltage to a (2^{N}−1)-th level read voltage; the third read voltage is one of the 2^{N}−1 read voltages, wherein N is a natural number.

Referring to FIG. 10, in some examples, the peripheral circuit is further configured to perform the following operations: operation S201, starting to set an offset read voltage; operation S202, receiving a read command; operation S203, retrieving the to-be-read block to be read according to the read command and whether the to-be-read block is an open block; operation S207, according to the to-be-read block not being an open block, for example, the to-be-read block is a close block, ending the offset read voltage setting, and performing a third read operation on a memory cell included in a page in the to-be-read block using the third read voltage. Alternatively, referring to FIG. 11, in some examples, the peripheral circuit is further configured to perform the following operations: operation S301, starting to set an offset read voltage; operation S302, receiving a read command; operation S303, retrieving the to-be-read block to be read according to the read command, whether the to-be-read block is an open block; operation S308, according to the to-be-read block not being an open block, for example, the to-be-read block is a close block, ending the offset read voltage setting, and performing a third read operation on a memory cell included in a page in the to-be-read block using the third read voltage.

According to a second aspect, an example of the present disclosure provides an operating method of a memory device, comprising: performing, by a peripheral circuit of the memory device coupled with a memory cell array of the memory device, a first read operation on a memory cell included in an edge page in a to-be-read block of a plurality of memory blocks of the memory cell array using a first offset read voltage according to the to-be-read block being an open block; the first offset read voltage has a first offset relative to a first read voltage; and the first read voltage is a read voltage corresponding to the first read operation in default read voltages of the to-be-read block.

In some examples, the open block includes at least one blank page including memory cells that are not programmed and at least one program page including memory cells that have been programmed; wherein the at least one program page includes an edge page which is adjacent to one of the at least one blank page in a stacking direction of the to-be-read block.

In some examples, the operating method includes: determining the first offset according to a number of program pages and a first coefficient; the first offset is positively correlated with the number of program pages and is negatively correlated with the first coefficient; and obtaining the first offset read voltage according to a difference between the first read voltage and the first offset.

In some examples, the operating method further includes: performing a first correction on the first coefficient according to a program-erase cycle number corresponding to the to-be-read block being in a first preset interval of a plurality of preset intervals, and determining that the first coefficient is a first value; and performing a second correction on the first coefficient according to the program-erase cycle number corresponding to the to-be-read block being in a second preset interval of the plurality of preset intervals which is different from the first preset interval, and determining that the first coefficient is a second value different from the first value; wherein each preset interval of the plurality of preset intervals includes at least one program-erase cycle number, and an average value of the preset interval is an average value of respective program-erase cycle numbers in the preset interval.

In some examples, the operating method further includes: performing a second read operation on a memory cell included in the inner page using a second offset read voltage; the second offset read voltage has a second offset relative to the second read voltage; the second read voltage is a read voltage corresponding to the second read operation in the default read voltages; wherein the second offset is less than the first offset; wherein the open block includes a plurality of program pages which include an edge page and an inner page.

In some examples, the operating method includes: determining the second offset according to the number of program pages and a second coefficient; the second offset is positively correlated with the number of program pages and is negatively correlated with the second coefficient; and obtaining the second offset read voltage according to a difference between the second read voltage and the second offset.

In some examples, the operating method further includes: performing a first correction on the second coefficient according to a program-erase cycle number corresponding to the to-be-read block being in a first preset interval of a plurality of preset intervals, and determining that the second coefficient is a first value; and performing a second correction on the second coefficient according to the program-erase cycle number corresponding to the to-be-read block being in a second preset interval of the plurality of preset intervals different from the first preset interval, and determining that the second coefficient is a second value different from the first value; wherein each preset interval of the plurality of preset intervals includes at least one program-erase cycle number, and an average value of the preset interval is an average value of respective program-erase cycle numbers in the preset interval.

In some examples, the operating method further includes: defining the plurality of preset intervals according to a preset program-erase cycle number of the memory device, the plurality of preset intervals comprise M intervals from a first interval to a M-th interval; wherein a number of the M intervals is positively correlated with a magnitude of the preset program-erase cycle number; wherein M is a positive integer and M≥2.

In some examples, the operating method further includes: determining the first offset or the second offset according to additional information; wherein the additional information includes a retention state or an interference state of the data stored in a memory cell included in the edge page or the inner page.

In some examples, the operating method further includes: performing a third read operation on a memory cell included in a page in the to-be-read block of the plurality of memory blocks using a third read voltage according to the to-be-read block being a close block; the third read voltage is a read voltage corresponding to the third read operation in the default read voltages; and memory cell included in any page of the close block have been programmed.

The memory device used in the operating method of the memory device according to the example of the present disclosure is the same as or similar to the memory device in the foregoing examples of the first aspect, and for technical features not described in details in the example of the present disclosure, reference may be made to the memory device in the foregoing examples of the first aspect for understanding, and details are not described herein again.

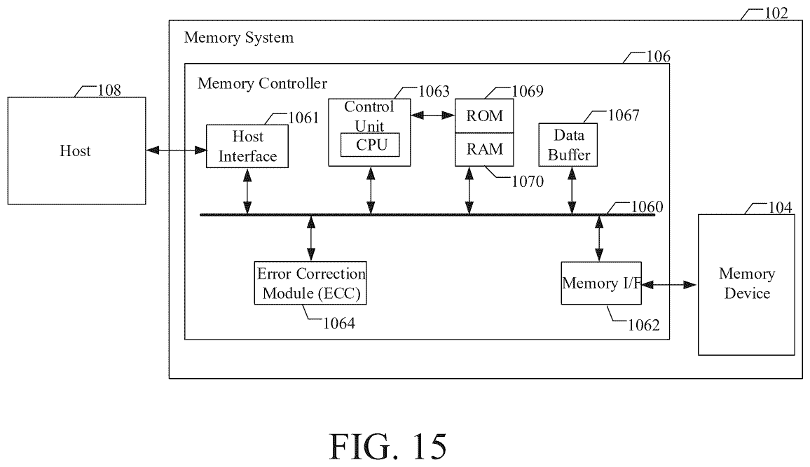

FIG. 15 is a schematic diagram of example of components structure with a memory system according to an example of the present disclosure.

According to a third aspect, an example of the present disclosure provides a memory system, referring to FIG. 15, the memory system 102 includes a memory device 104 and a memory controller 106 coupled with the memory device 104 and controlling the memory device 104; the memory controller is configured to: send a read command; and the memory device is further configured to: receive a read command, and perform a first read operation on a memory cell included in an edge page in a to-be-read block of the memory device using a first offset read voltage; the first offset read voltage has a first offset relative to a first read voltage; and the first read voltage is a read voltage corresponding to the first read operation in default read voltages of the to-be-read block.

The memory device 104 may be understood with reference to the related descriptions of the memory device 104 shown in FIG. 1, FIG. 2A, and FIG. 2B.

As shown in FIG. 15, in some examples, the memory system 102 is coupled with a host, and performs various feedback in response to an instruction of the host. The memory system 102 may include a memory controller 106 and a memory device 104, the memory controller 106 is configured to control the memory device 104 to perform operations such as read, write, and erase, and the memory controller 106 and the memory device 104 may be coupled in any suitable manner.

The memory controller 106 may include a host interface (I/F) 1061, a memory interface (I/F) 1062, a control unit 1063, a read-only memory (ROM) 1069, a random access memory (RAM) 1070, an error correction module 1064, a garbage collection module 1065, a wear leveling module 1066, a data buffer 1067, and a bus 1060. The host interface 1061 is a connection interface to connect the host 108 and the memory controller 106, and the host interface 1061 allows the host and the memory controller to communicate according to a specific protocol, send read and write requests, and perform other operations. The memory interface 1062 is a connection interface between the memory controller 106 and the memory device 104, and the memory interface 1062 is configured to implement data transmission between the memory controller 106 and the memory device 104. The control unit 1063 is configured to control the memory controller 106 as a whole, and the operations performed by the memory controller in previous description are mainly performed and completed by the control unit 1063 herein. In some examples, the control unit 1063 is, for example, a central processing unit (CPU), a microprocessor (MCU), or the like. ROM 1069 may include firmware (FW) or firmware program code of memory controller 106 for initializing and operating various components of a memory controller, and RAM 1070 may be configured to buffer data. The error correction module 1064 may further include an encoding unit and a decoding unit; the encoding unit is configured to encode the to-be-stored data to obtain check data, and the decoding unit is configured to decode the check data to detect and correct possible error data in a data transmission process. In some examples, the firmware may be a program that is stored in an electrically erasable programmable ROM (EEPROM) or a FLASH chip of the memory system and upgraded by the host through a refresh program. The firmware controls the algorithms for read/write and transfer of the memory system and reasonably allocates the storage of the data.

In some examples, the memory system is configured to implement the operating method of any one of one or more memory devices according to the second aspect through firmware. In this way, the plurality of word line groups do not need to be divided, the first offset is adjusted in a linear relationship, the algorithm logic complexity of the firmware can be reduced, the code development difficulty is reduced, meanwhile, the reduction of the memory space occupied by the managed first offset table is more refined for the first offset management of the open block, and the fail bit count of the first read operation is reduced.

In some examples, the memory system 102 includes any one of one or more memory devices 104 according to the first aspect; and a memory controller 106 coupled with the memory device 104 and controlling the memory device 104. In some examples, the memory device includes a memory cell array comprising a plurality of memory blocks, and a peripheral circuit coupled with the memory cell array and configured to: perform a first read operation on a memory cell included in an edge page in a to-be-read block of the plurality of memory blocks using a first offset read voltage according to the to-be-read block being an open block; the first offset read voltage has a first offset relative to a first read voltage; and the first read voltage is a read voltage corresponding to the first read operation in default read voltages of the to-be-read block.

In some examples, the memory controller is further configured to: send a first instruction indicating to obtain the first offset read voltage; the memory device is further configured to: receive the first instruction, and obtain first information representing the first offset read voltage; and send to the memory controller second information representing that the first information is obtained; the memory controller is further configured to: send a read command according to the second information; and the memory device is further configured to: receive the read command, generate a first offset read voltage according to the first information, and control the memory device to perform the first read operation according to the first offset read voltage.

In some examples, the first instruction may be implemented by a set feature command.

In some examples, the memory controller is configured to: send a first instruction which includes open block information; the open block information includes information representing that the to-be-read block is an open block, information representing that a to-be-read page in the to-be-read block is an edge page, and information representing that the first offset is associated with the edge page; and the memory device is configured to: receive the first instruction, and obtain first information representing the first offset read voltage based on the open block information; and send to the memory controller second information representing that the first information is obtained.

In some examples, the memory controller is further configured to: send a read command; the read command includes a first instruction indicating to obtain the first offset read voltage; the memory device is further configured to: receive the read command, and obtain first information representing the first offset read voltage; and generate a first offset read voltage according to the first information, and control the memory device to perform the first read operation according to the first offset read voltage. In some examples, a portion of the field of the read command is configured to set the first instruction; and the first instruction may be implemented by a set feature command.

In some examples, the memory controller is configured to: send a read command; the read command includes a first instruction which includes open block information; the open block information includes information representing that the to-be-read block is an open block, information representing that a to-be-read page in the to-be-read block is an edge page, and information representing that the first offset is associated with the edge page; and the memory device is configured to: receive the read command, and obtain first information representing the first offset read voltage based on the open block information.

In some examples, the open block information further includes information representing a number of program pages in the to-be-read block and information representing a first coefficient; the information representing that the first offset is associated with the edge page includes information representing that the first offset is positively correlated with the number of program pages and is negatively correlated with the first coefficient; the memory device is configured to: determine information representing the first offset based on the information representing the number of program pages and the information representing the first coefficient, and the information representing that the first offset is positively correlated with the number of program pages and is negatively correlated with the first coefficient; and obtain the information representing the first offset read voltage according to the information representing the first read voltage and the information representing the first offset.

In some examples, the open block includes at least one blank page including memory cells that are not programmed and at least one program page including memory cells that have been programmed; wherein the at least one program page includes an edge page which is adjacent to one of the at least one blank page in a stacking direction of the to-be-read block; the open block includes a plurality of program pages which include an edge page and an inner page; the memory device is further configured to: perform a second read operation on a memory cell included in the inner page using a second offset read voltage; the second offset read voltage has a second offset relative to the second read voltage; the second read voltage is a read voltage corresponding to the second read operation in the default read voltages; wherein the second offset is less than the first offset.

In some examples, the open block information further includes information representing the number of program pages in the to-be-read block and information representing a second coefficient; the information representing that the second offset is associated with the edge page includes information representing that the second offset is positively correlated with the number of program pages and is negatively correlated with the second coefficient; the memory device is configured to: determine information representing the second offset based on the information representing the number of program pages and the information representing the second coefficient, and the information representing that the second offset is positively correlated with the number of program pages and is negatively correlated with the second coefficient; and obtain the information representing the second offset read voltage according to the information representing the second read voltage and the information representing the second offset; wherein the second offset is less than the first offset.

Referring to FIG. 15 and FIG. 5, in some examples, in response to the memory system 102 being restarted, the open block information is initialized by scanning the memory cell array 301 (as shown in FIG. 5) or restoring a backup copy of the open block information, wherein the open block information includes information representing that the to-be-read block is an open block, information representing that the to-be-read page in the to-be-read block is an edge page, information about a number of program pages in the to-be-read block, information about the first coefficient, and information representing that the first offset is positively correlated with the number of program pages and is negatively correlated with the first coefficient. In some examples, the host 108 (shown in FIG. 15) is configured to initialize the open block information. In some examples, the open block information for one or more open blocks of the plurality of memory blocks may be stored, for example, in register 514 (shown in FIG. 5). In some examples, the open block information may be updated by the control logic 512 in a program operation on the memory cell array 301.

In some examples, according to the to-be-read block of the plurality of memory blocks being an open block, the to-be-read page in the to-be-read block being an edge page, the number of program pages in the to-be-read block, the information of the first coefficient, and the first offset being positively correlated with the number of program pages and being negatively correlated with the first coefficient, determine information representing the first offset; obtain the information representing the first offset read voltage according to the information representing the first read voltage and the information representing the first offset; generate a first offset read voltage according to the information representing the first offset read voltage, and perform the first read operation on the memory cell in the to-be-read block using the first offset read voltage having the first offset relative to the first read voltage; wherein the first read voltage is a read voltage corresponding to the first read operation in the default read voltages of the to-be-read block. For example, the control logic 512 may determine a first offset according to the open block information, determine a first offset read voltage according to the first offset and the first read voltage, control the voltage generator 510 to provide a first offset read voltage, and control the word line driver 508 to apply the first offset read voltage to a word line coupled with a memory cell in the open block.

In some examples, the open block information further includes information of a second coefficient, and information representing that the second offset is positively correlated with the number of program pages and is negatively correlated with the second coefficient. In some examples, according to the to-be-read block of the plurality of memory blocks being an open block, the to-be-read page in the to-be-read block being an inner page, the number of program pages in the to-be-read block, the information of the second coefficient, and the second offset being positively correlated with the number of program pages and being negatively correlated with the second coefficient, determine information representing the second offset; obtain the information representing the second offset read voltage according to the information representing the second read voltage and the information representing the second offset; generate a second offset read voltage according to the information representing the second offset read voltage, and perform the second read operation on the memory cell in the to-be-read block using the second offset read voltage having the second offset relative to the second read voltage; wherein the second read voltage is a read voltage corresponding to the second read operation in the default read voltages of the to-be-read block. For example, the control logic 512 may determine a second offset according to the open block information, determine a second offset read voltage according to the second offset and the second read voltage, control the voltage generator 510 to provide a second offset read voltage, and control the word line driver 508 to apply the second offset read voltage to the word line coupled with the memory cell in the open block.

In some examples, the to-be-read block of the plurality of memory blocks is a close block, and perform the third read operation on the memory cell included in the to-be-read page in the to-be-read block using the third read voltage, wherein the third read voltage is a read voltage corresponding to the third read operation in the default read voltages of the to-be-read block. For example, the control logic 512 may determine a third read voltage, control the voltage generator 510 to provide a third read voltage, and control the word line driver 508 to apply a third read voltage to a word line coupled with a memory cell in the close block.

It should be understood that reference throughout the description to “one example” or “an example” means that a particular feature, structure or characteristic related to the example is included in at least one example of the present disclosure. Thus, terms “in one example” or “in an example” throughout the description are not necessarily referring to a same example. Furthermore, these particular features, structures or characteristics may be combined in any appropriate manner in one or more examples. It should be understood that in various examples of the present disclosure, sequence numbers of the processes described above do not mean the execution order, and the execution order of each process is to be determined by its function and internal logic, and should not constitute any limitation to implementation process of examples of the present disclosure. The serial numbers of examples of the present disclosure described above are for the purpose of description only, and do not represent the advantages and disadvantages of the examples.

The above description is only a preferred implementation of the present disclosure, and is not intended to limit the scope of the present disclosure, and under the idea of the present disclosure, any equivalent structural transformation made by using the present disclosure and the accompanying drawings or any direct/indirect application of the present disclosure to other related technical fields fall into the scope of the present disclosure.

What is claimed is:

1. A memory device, comprising:
a memory cell array comprising a plurality of memory blocks, and
a peripheral circuit coupled with the memory cell array and configured to:
perform a first read operation on a memory cell included in an edge page in a to-be-read block of the plurality of memory blocks using a first offset read voltage according to the to-be-read block being an open block, wherein the first offset read voltage has a first offset relative to a first read voltage, and the first read voltage is a read voltage corresponding to the first read operation in default read voltages of the to-be-read block.

2. The memory device of claim 1, wherein the open block comprises at least one blank page including memory cells that are not programmed and at least one program page including memory cells that have been programmed, wherein the at least one program page comprises the edge page which is adjacent to one of the at least one blank page in a stacking direction of the to-be-read block.

3. The memory device of claim 2, wherein the peripheral circuit is configured to:
determine the first offset according to a number of program pages and a first coefficient, wherein the first offset is positively correlated with the number of program pages and is negatively correlated with the first coefficient; and
obtain the first offset read voltage according to a difference between the first read voltage and the first offset.

4. The memory device of claim 3, wherein the peripheral circuit is further configured to:
perform a first correction on the first coefficient according to a program-erase cycle number corresponding to the to-be-read block being in a first preset interval of a plurality of preset intervals, and determine that the first coefficient is a first value; and
perform a second correction on the first coefficient according to the program-erase cycle number corresponding to the to-be-read block being in a second preset interval of the plurality of preset intervals which is different from the first preset interval, and determine that the first coefficient is a second value different from the first value,
wherein each preset interval of the plurality of preset intervals comprises at least one program-erase cycle number, and an average value of the preset interval is an average value of respective program-erase cycle numbers in the preset interval.

5. The memory device of claim 2, wherein the open block comprises a plurality of program pages which comprise the edge page and an inner page, and the peripheral circuit is further configured to:
perform a second read operation on a memory cell included in the inner page using a second offset read voltage, wherein the second offset read voltage has a second offset relative to a second read voltage, and the second read voltage is a read voltage corresponding to the second read operation in the default read voltages, wherein the second offset is less than the first offset.

6. The memory device of claim 5, wherein the peripheral circuit is configured to:
determine the second offset according to a number of program pages and a second coefficient, wherein the second offset is positively correlated with the number of program pages and is negatively correlated with the second coefficient; and
obtain the second offset read voltage according to a difference between the second read voltage and the second offset.

7. The memory device of claim 6, wherein the peripheral circuit is further configured to:
perform a first correction on the second coefficient according to a program-erase cycle number corresponding to the to-be-read block being in a first preset interval of a plurality of preset intervals, and determine that the second coefficient is a first value; and
perform a second correction on the second coefficient according to the program-erase cycle number corresponding to the to-be-read block being in a second preset interval of the plurality of preset intervals which is different from the first preset interval, and determine that the second coefficient is a second value different from the first value,
wherein each preset interval of the plurality of preset intervals comprises at least one program-erase cycle number, and an average value of the preset interval is an average value of respective program-erase cycle numbers in the preset interval.

8. The memory device of claim 4, wherein the peripheral circuit is further configured to:
define the plurality of preset intervals according to a preset program-erase cycle number of the memory device, wherein the plurality of preset intervals comprise M intervals from a first interval to a M-th interval, wherein a number of the M intervals is positively correlated with a magnitude of the preset program-erase cycle number, wherein M is a positive integer and M≥2.

9. The memory device of claim 5, wherein the peripheral circuit is further configured to:
determine the first offset or the second offset according to additional information, wherein the additional information comprises a retention state or an interference state of data stored in a memory cell included in the edge page or the inner page.

10. The memory device of claim 2, wherein the peripheral circuit is further configured to:
perform a third read operation on a memory cell included in a page in the to-be-read block of the plurality of memory blocks using a third read voltage according to the to-be-read block being a close block, wherein the third read voltage is a read voltage corresponding to the third read operation in the default read voltages, and memory cells included in any page of the close block have been programmed.

11. The memory device of claim 1, wherein a number of bits stored in the memory cell is N, and the memory cell has 2^{N} memory states, and wherein the 2^{N} memory states comprise an erase state and 2^{N}−1 non-erase states, wherein N is a positive integer,
the default read voltages comprise 2^{N}−1 read voltages from a first level read voltage to a (2^{N}−1)-th level read voltage, wherein the first read voltage is one of 2^{N}−1 read voltages, and the first offset is associated with the first read voltage.

12. The memory device of claim 11, wherein the first offset is determined to be a first value according to the first read voltage being a read voltage of the 2^{N}−1 read voltages; and
the first offset is determined to be a second value different from the first value according to the first read voltage being another read voltage of the 2^{N}−1 read voltages which is different from the read voltage.

13. An operating method of a memory device, comprising:
performing, by a peripheral circuit of the memory device coupled with a memory cell array of the memory device, a first read operation on a memory cell included in an edge page in a to-be-read block of a plurality of memory blocks of the memory cell array using a first offset read voltage according to the to-be-read block being an open block, wherein the first offset read voltage has a first offset relative to a first read voltage, and the first read voltage is a read voltage corresponding to the first read operation in default read voltages of the to-be-read block.

14. A memory system, comprising:
a memory device configured to:
receive a read command, and
perform a first read operation on a memory cell included in an edge page in a to-be-read block of the memory device using a first offset read voltage, wherein the first offset read voltage has a first offset relative to a first read voltage, and the first read voltage is a read voltage corresponding to the first read operation in default read voltages of the to-be-read block; and
a memory controller coupled with the memory device and controlling the memory device, wherein the memory controller is configured to send the read command.

15. The memory system of claim 14, wherein the memory controller is further configured to: send a first instruction indicating to obtain the first offset read voltage;
the memory device is further configured to: receive the first instruction, and obtain first information representing the first offset read voltage; and send to the memory controller second information representing that the first information is obtained;
the memory controller is further configured to: send the read command according to the second information; and
the memory device is further configured to: receive the read command, generate the first offset read voltage according to the first information, and control the memory device to perform the first read operation according to the first offset read voltage.

16. The memory system of claim 15, wherein the memory controller is configured to: send the first instruction which comprises open block information, wherein the open block information comprises information representing that the to-be-read block is an open block, information representing that a to-be-read page in the to-be-read block is an edge page, and information representing that the first offset is associated with the edge page; and
the memory device is configured to: receive the first instruction, and obtain the first information representing the first offset read voltage based on the open block information; and send to the memory controller the second information representing that the first information is obtained.

17. The memory system of claim 14, wherein the memory controller is further configured to:
send the read command, wherein the read command comprises a first instruction indicating to obtain the first offset read voltage;
the memory device is further configured to: receive the read command, and obtain first information representing the first offset read voltage; and
generate the first offset read voltage according to the first information, and control the memory device to perform the first read operation according to the first offset read voltage.

18. The memory system of claim 17, wherein the memory controller is configured to: send the read command, wherein the read command comprises the first instruction which comprises open block information, wherein the open block information comprises information representing that the to-be-read block is an open block, information representing that a to-be-read page in the to-be-read block is an edge page, and information representing that the first offset is associated with the edge page; and
the memory device is configured to: receive the read command, and obtain the first information representing the first offset read voltage based on the open block information.

19. The memory system of claim 16, wherein the open block information further comprises information representing a number of program pages in the to-be-read block and information representing a first coefficient, wherein the information representing that the first offset is associated with the edge page comprises information representing that the first offset is positively correlated with the number of program pages and is negatively correlated with the first coefficient;
the memory device is configured to: determine information representing the first offset based on the information representing the number of program pages and the information representing the first coefficient, and the information representing that the first offset is positively correlated with the number of program pages and is negatively correlated with the first coefficient; and obtain the information representing the first offset read voltage according to information representing the first read voltage and the information representing the first offset.

20. The memory system of claim 19, wherein the open block comprises at least one blank page including memory cells that are not programmed and at least one program page including memory cells that have been programmed, wherein the at least one program page comprises the edge page which is adjacent to one of the at least one blank page in a stacking direction of the to-be-read block, and wherein the open block comprises a plurality of program pages which comprise the edge page and an inner page;
the memory device is further configured to:
perform a second read operation on a memory cell included in the inner page using a second offset read voltage, wherein the second offset read voltage has a second offset relative to a second read voltage, and the second read voltage is a read voltage corresponding to the second read operation in the default read voltages, wherein the second offset is less than the first offset.
